(19) United States
(12) Patent Application Publication
(10) Pub. No.: US 2022/0376144 A1
(43) Pub. Date: Nov. 24, 2022

(54) LIGHT-EMITTING DIODE AND DISPLAY DEVICE COMPRISING SAME

(71) Applicant: Samsung Display Co., LTD., Yongin-si, Gyeonggi-do (KR)

(72) Inventors: Moon Jung AN, Hwaseong-si (KR); Sung Chan JO, Seoul (KR); Hoo Keun PARK, Cheongju-si (KR); Chul Jong YOO, Seongnam-si (KR); Hye Lim KANG, Hwaseong-si (KR); Dong Gyun KIM, Seoul (KR); Dong Eon LEE, Hwaseong-si (KR); Hyun Min CHO, Seoul (KR)

(21) Appl. No.: 17/636,218

(22) PCT Filed: Feb. 27, 2020
(86) PCT No.: PCT/KR2020/002785

§ 371 Date: Aug. 15, 2022

(30) Foreign Application Priority Data
Sep. 16, 2019 (KR) 10-2019-0113759

(51) Int. Cl. H01L 33/44; H01L 25/16; H01L 23/00; H01L 33/42

(52) U.S. Cl. CPC H01L 33/44; H01L 25/167; H01L 24/24; H01L 33/42; H01L 33/0093

(57) ABSTRACT

A light emitting element includes: a first semiconductor layer doped with a first polarity; a second semiconductor layer doped with a second polarity different from the first polarity; an active layer between the first semiconductor layer and the second semiconductor layer in a first direction; and an insulating film surrounding an outer surface of at least the active layer and extending in the first direction. A thickness of a first portion of the insulating film surrounding the active layer is in a range of 10% to 16% of a diameter of the active layer.

### CROSS-REFERENCE TO RELATED APPLICATION

This application is a U.S. National Phase Patent Application of International Patent Application Number PCT/KR2020/002785, filed on Feb. 27, 2020, which claims priority to Korean Patent Application Number 10-2019-0113759, filed on Sep. 16, 2019, the entire content of all of which is incorporated herein by reference.

### BACKGROUND

### 1. Field

The present disclosure relates to a light emitting element and a display device including the same.

### 2. Description of the Related Art

The importance of display devices has steadily increased with the development of multimedia technology. In response thereto, various types of display devices, such as an organic light emitting diode (OLED) display, a liquid crystal display (LCD), and the like have been developed.

A display device is a device for displaying (or configured to display) an image and generally includes a display panel, such as an organic light emitting diode display panel or a liquid crystal display panel. The light emitting display panel may include light emitting elements, for example, light emitting diodes (LED). Examples of the light emitting diode include an organic light emitting diode (OLED) using an organic material as a fluorescent material and an inorganic light emitting diode using an inorganic material as a fluorescent material.

Inorganic LEDs using an inorganic material (e.g., an inorganic semiconductor) as a fluorescent material are durable even in a high-temperature environment and have higher blue light efficiency than OLEDs. In addition, a transfer method using dielectrophoresis (DEP) has been developed for a manufacturing process to overcome limitations of conventional inorganic LEDs. Therefore, research is being continuously conducted on inorganic LEDs, which have better durability and efficiency than OLEDs.

### SUMMARY

Aspects of the present disclosure provide a light emitting element including a thick electrode layer and a thick insulating film (e.g., a relatively thick electrode layer and a relatively thick insulating film) to protect an active layer.

Aspects of the present disclosure also provide a display device including the light emitting element and having improved luminous reliability.

It should be noted that aspects of the present disclosure are not limited thereto and other aspects, which are not mentioned herein, will be apparent to those of ordinary skill in the art from the following description.

According to an embodiment of the present disclosure, a light emitting element includes: a first semiconductor layer doped with a first polarity; a second semiconductor layer doped with a second polarity different from the first polarity; an active layer between the first semiconductor layer and the second semiconductor layer in a first direction; and an insulating film surrounding an outer surface of at least the active layer and extending in the first direction. A thickness of a first portion of the insulating film surrounding the active layer is in a range of 10% to 16% of a diameter of the active layer.

The diameter of the active layer may be in a range of 500 nm to 600 nm, and the thickness of the first portion of the insulating film may be in a range of 60 nm to 80 nm.

The insulating film may have a second portion extending from the first portion and covering a portion of a side surface of the second semiconductor layer, and a thickness of the second portion may be smaller than a thickness of the first portion.

A portion of the insulating film surrounding an interface between the active layer and the second semiconductor layer may have a thickness of at least 20 nm.

The second portion may have a curved outer surface such that its thickness decreases in the first direction.

The light emitting element may further include an electrode layer on the second semiconductor layer, and a thickness of the electrode layer may be greater than a thickness of the second semiconductor layer.

The electrode layer may have a thickness in a range of 20 nm to 200 nm.

The insulating film may surround a side surface of the electrode layer.

The insulating film may surround a portion of a side surface of the electrode layer, a top surface of the electrode layer may be exposed by the insulating film, and the side surface of the electrode layer may be partially exposed by the insulating film.

The insulating film may have a third portion connected to the first portion and surrounding a portion of the side surface of the electrode layer, and a thickness of the third portion may be smaller than a thickness of the first portion.

The third portion of the insulating film may have a curved outer surface such that its thickness decreases in the first direction.

According to an embodiment of the present disclosure, a display device includes: a substrate; a first electrode on the substrate and a second electrode spaced apart from the first electrode; a light emitting element between the first electrode and the second electrode and electrically connected to the first electrode and the second electrode; a first insulating layer under the light emitting element between the first electrode and the second electrode; and a second insulating layer on the light emitting element and exposing one end and another end of the light emitting element. The light emitting element includes: a first semiconductor layer doped with a first polarity; a second semiconductor layer doped with a second polarity different from the first polarity; an active layer between the first semiconductor layer and the second semiconductor layer in a first direction; and an insulating film surrounding an outer surface of at least the active layer and extending in the first direction. The insulating film includes a first portion surrounding the one end of the light emitting element and the active layer, a second portion contacting the second insulating layer, and a third portion surrounding the other end of the light emitting element, and a thickness of the second portion is greater than that of the first portion and the third portion.

The display device may further include: a first contact electrode contacting the first electrode and the one end of the light emitting element; and a second contact electrode contacting the second electrode and the other end of the light emitting element.

The light emitting element may further include an electrode layer on the second semiconductor layer and having a thickness greater than that of the second semiconductor layer. The first contact electrode may contact the first portion of the insulating film and the electrode layer, and the second contact electrode may contact the third portion of the insulating film and the first semiconductor layer.

The first portion of the insulating film may surround a portion of a side surface of the electrode layer, a top surface of the electrode layer may be exposed by the insulating film, and the side surface of the electrode layer may be partially exposed by the insulating film.

The first contact electrode may contact a portion of the side surface and the top surface of the electrode layer.

The first portion of the insulating film may have a curved outer surface such that its thickness decreases in the first direction.

In the first portion, a first thickness measured at an interface between the second semiconductor layer and the electrode layer and a second thickness measured at an interface between the second semiconductor layer and the active layer may satisfy the following Equation (1):

θc=arctan((W2′−W1′)/D)≤70° Equation 1

wherein: θc is an inclination angle of an inclined outer surface of the first portion of the insulating film; W1′ is a thickness measured at an interface between the electrode layer and the second semiconductor layer in the first portion of the insulating film; W2′ is a thickness measured at an interface between the second semiconductor layer and the active layer in the first portion of the insulating film; and D is a thickness of the second semiconductor layer.

The second thickness may be 20 nm or more, and a thickness of the first portion surrounding the active layer may be 40 nm or more.

The electrode layer may have a thickness in a range of 20 nm to 200 nm.

A thickness of the second portion may be in a range of 10% to 16% of a diameter of the active layer.

The diameter of the active layer may be in a range of 500 nm to 600 nm, and the thickness of the second portion of the insulating film may be in a range of 60 nm to 80 nm.

A first diameter of the light emitting element measured at the second portion of the insulating film may be greater than a second diameter of the light emitting element measured at the first portion of the insulating film and a third diameter of the light emitting element measured at the third portion of the insulating film.

Details of other embodiments are included in the detailed description and the accompanying drawings.

A light emitting element, according to one embodiment of the present disclosure, includes an electrode layer having a thickness greater than that of a second semiconductor layer and an insulating film in which a portion surrounding the active layer has a thickness of a certain level or more. The light emitting element may prevent the electrode layer from being removed during a manufacturing process and may safely protect the active layer even if the insulating film is partially etched.

Accordingly, the display device according to embodiments of the present disclosure including the light emitting element may exhibit improved luminous efficiency and luminous reliability.

The aspects and features according to the embodiments of the present disclosure are not limited by those described above, and other various aspects and features are included in this disclosure and will be understood by those of ordinary skill in the art.

### BRIEF DESCRIPTION OF DRAWINGS

FIG. 1 is a schematic plan view of a display device according to one embodiment.

FIG. 2 is a schematic plan view of one pixel of a display device according to one embodiment.

FIG. 3 is a plan view illustrating one sub-pixel shown in FIG. 2.

FIG. 4 is a cross-sectional view taken along the lines Xa-Xa′, Xb-Xb′, and Xc-Xc′ of FIG. 3.

FIG. 5 is a schematic diagram of a light emitting element according to one embodiment.

FIG. 6 is a schematic cross-sectional view of a light emitting element according to one embodiment.

FIG. 7 is an enlarged view of the part QA of FIG. 4.

FIG. 8 an enlarged view of the part QA of FIG. 4 according to another embodiment.

FIGS. 9 to 14 are cross-sectional views show steps of a manufacturing process of a light emitting element according to one embodiment.

FIGS. 15 to 19 are cross-sectional views illustrating some steps of a manufacturing process of a display device according to one embodiment.

FIG. 20 is a schematic cross-sectional view of a light emitting element according to one embodiment.

FIG. 21 is a cross-sectional view partially illustrating a manufacturing process of the light emitting element shown in FIG. 20.

FIG. 22 is a cross-sectional view illustrating a part of the display device including the light emitting element shown in FIG. 20.

FIG. 23 is a schematic cross-sectional view of a light emitting element according to one embodiment.

FIG. 24 is a cross-sectional view illustrating a part of the display device including the light emitting element shown in FIG. 23.

FIG. 25 is a plan view illustrating one sub-pixel of a display device according to one embodiment.

FIG. 26 is a plan view illustrating one pixel of a display device according to one embodiment.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing particular example embodiments of the present disclosure and is not intended to be limiting of the described example embodiments of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Hereinafter, embodiments will be described with reference to the accompanying drawings.

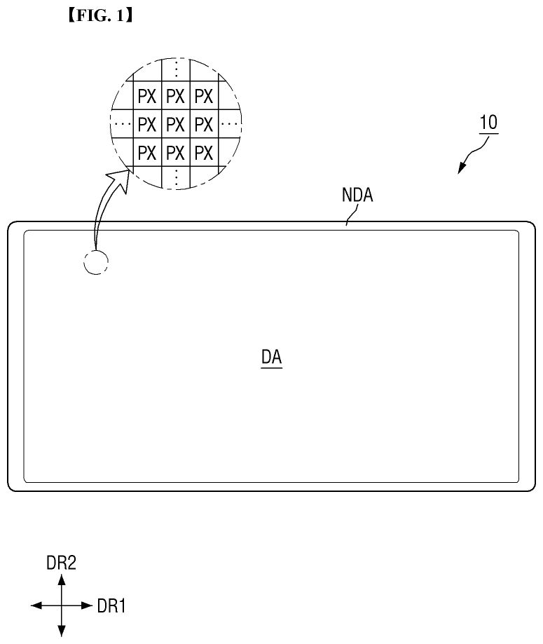

FIG. 1 is a schematic plan view of a display device according to one embodiment.

Referring to FIG. 1, a display device 10 displays (e.g., is configured to display) a moving image and/or a still image. The display device 10 may refer to any electronic device including a display screen. Examples of the display device 10 may include a television, a laptop computer, a monitor, a billboard, an Internet-of-Things (loT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder, and the like that include a display screen.

The display device 10 includes a display panel which provides a display screen. Examples of the display panel may include an LED display panel, an organic light emitting diode display panel, a quantum dot light emitting display panel, a plasma display panel, and a field emission display panel. In the following description, an example in which the display panel is an LED display panel will be described, but the present disclosure is not limited thereto, and other display panels may be applied within the same scope of the present disclosure.

The shape of the display device 10 may be variously modified. For example, the display device 10 may have a shape, such as a rectangular shape elongated in a horizontal direction, a rectangular shape elongated in a vertical direction, a square shape, a quadrilateral shape with rounded corners (e.g., vertices), another polygonal shape, and a circular shape. The shape of a display area DA of the display device 10 may be similar to the overall shape of the display device 10. In FIG. 1, the display device 10 and the display area DA have a rectangular shape elongated in the horizontal direction.

The display device 10 may have the display area DA and a non-display area NDA. The display area DA is an area where an image can be displayed, and the non-display area NDA is an area where an image is not displayed. The display area DA may also be referred to as an active region, and the non-display area NDA may also be referred to as a non-active region.

The display area DA may substantially occupy the center of the display device 10. The display area DA may include a plurality of pixels PX. The plurality of pixels PX may be arranged in a matrix. The shape of each pixel PX may be a rectangular or square shape in a plan view. However, the present disclosure is not limited thereto, and each pixel PX may have a rhombic shape in which each side is inclined with respect to one direction. Each of the pixels PX may include one or more light emitting elements 300 that emit light of a specific wavelength band to display a specific color.

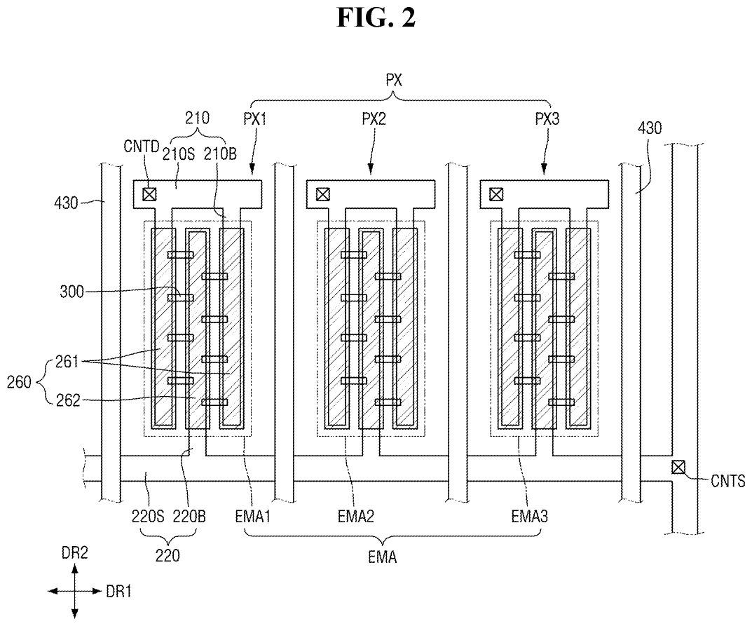

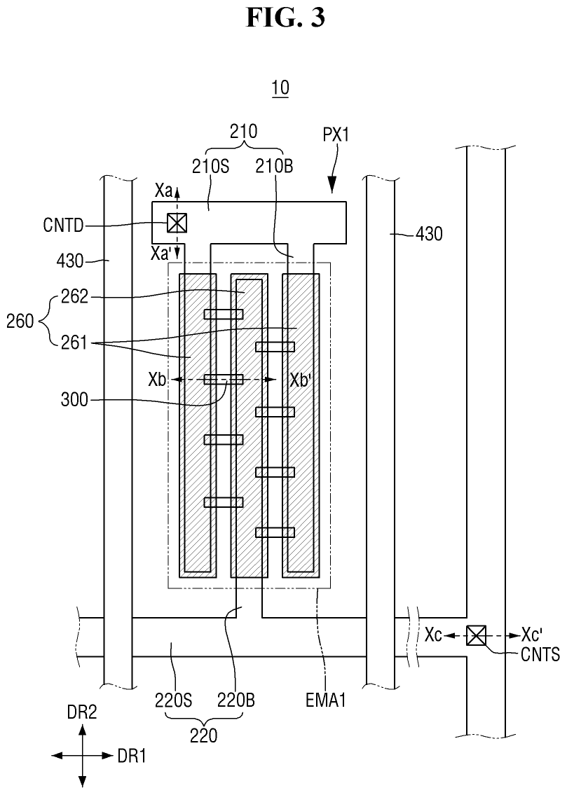

FIG. 2 is a schematic plan view of one pixel of a display device according to one embodiment. FIG. 3 is a plan view illustrating one sub-pixel shown in FIG. 2.

Referring to FIGS. 2 and 3, each of the pixels PX may include a first sub-pixel PX1, a second sub-pixel PX2, and a third sub-pixel PX3. The first sub-pixel PX1 may emit light of a first color, the second sub-pixel PX2 may emit light of a second color, and the third sub-pixel PX3 may emit light of a third color. The first color may be blue, the second color may be green, and the third color may be red. However, the present disclosure is not limited thereto, and the sub-pixels PXn may emit the same color light. In addition, although FIG. 2 illustrates an embodiment in which the pixel PX includes three sub-pixels PXn, the present disclosure is not limited thereto, and the pixel PX may include a greater number of sub-pixels PXn.

Each sub-pixel PXn of the display device 10 may include a region defined as an emission area EMA. The first sub-pixel PX1 may include a first emission area EMA1, the second sub-pixel PX2 may include a second emission area EMA2, and the third sub-pixel PX3 may include a third emission area EMA3. The emission area EMA may be defined as a region where the light emitting elements 300 included in the display device 10 are disposed to emit light of a specific wavelength band. The light emitting element 300 includes an active layer 330, and the active layer 330 may emit light of a specific wavelength band without directionality. Light emitted from the active layer 330 of the light emitting element 300 may be radiated in a lateral direction of the light emitting element 300 as well as in directions of both ends (e.g., opposite ends) of the light emitting element 300. The emission area EMA of each sub-pixel PXn may include a region adjacent to the light emitting element 300 where the light emitted from the light emitting element 300 is radiated, including the region where the light emitting element 300 is disposed. Further, without being limited thereto, the emission area EMA may also include a region where the light emitted from the light emitting element 300 is reflected or refracted by another member and emitted. The plurality of light emitting elements 300 may be disposed in the respective sub-pixels PXn, and the emission area EMA may include an area where the light emitting element 300 is disposed and an area adjacent thereto.

Each sub-pixel PXn of the display device 10 may include a non-emission area defined as a region other than the emission area EMA. The non-emission area may be a region in which the light emitting element 300 is not disposed and a region from which light is not emitted because light emitted from the light emitting element 300 does not reach it.

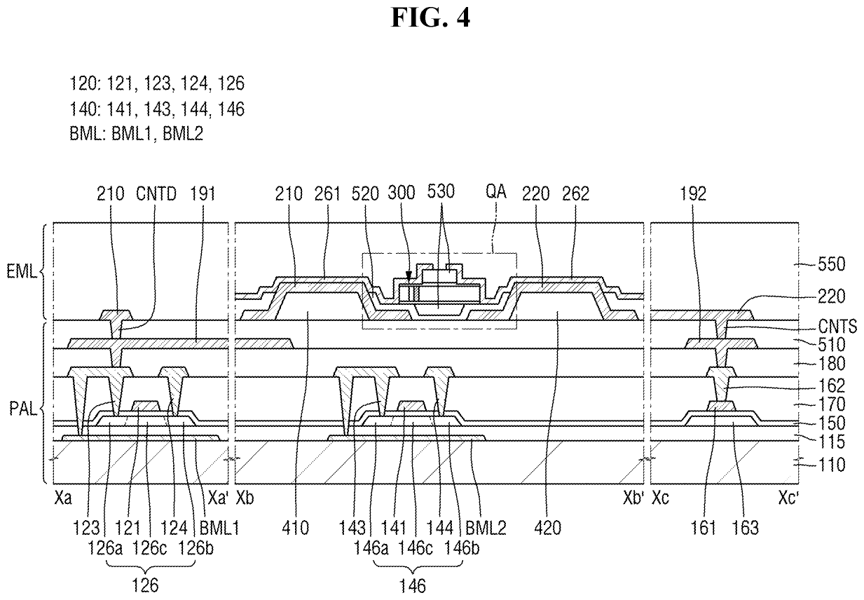

Each sub-pixel PXn of the display device 10 may include a plurality of electrodes 210 and 220, the light emitting element 300, a plurality of contact electrodes 260, and a plurality of external banks 430. The display device 10 may further include a plurality of internal banks 410 and 420 and a plurality of insulating layers 510, 520, 530 and 550 (see, e.g., FIG. 4).

The plurality of electrodes 210 and 220 may include a first electrode 210 and a second electrode 220. The first and second electrodes 210 and 220 may include respective electrode stems 210S and 220S arranged to extend in a first direction DR1 and respective electrode branches 210B and 220B extending from the respective electrode stems 210S and 220S in a second direction DR2 crossing (e.g., intersecting) the first direction DR1.

The first electrode 210 may include the first electrode stem 210S extending in the first direction DR1, and at least one electrode branch 210B branched from (e.g., branched off from) the first electrode stem 210S and extending in the second direction DR2.

The first electrode stems 210S of any one pixel may be arranged such that both ends of the individual first electrode stems 210S are terminated with gaps between the respective sub-pixels PXn, and each first electrode stem 210S may be arranged along substantially a same straight line as the first electrode stem 210S of the sub-pixel adjacent to it in the same row (e.g., in the first direction DR1). Because the first electrode stems 210S disposed in the respective sub-pixels PXn are arranged such that both ends thereof are spaced apart from each other (e.g., are physically and electrically disconnected or isolated from each other), different electric signals may be applied to the first electrode branches 210B in different sub-pixels PXn.

The first electrode branch 210B may be branched from at least a part of the first electrode stem 210S, may extend in the second direction DR2 and may be terminated while being spaced apart from the second electrode stem 220S, which is disposed to face the first electrode stem 210S.

The second electrode 220 may include the second electrode stem 220S extending in the first direction DR1 and disposed to face the first electrode stem 210S while being distanced (e.g., spaced) apart from it in the second direction DR2; and the second electrode branch 220B may be branched from the second electrode stem 220S and may extend in the second direction DR2. The second electrode stem 220S may be connected at the other end to the second electrode stem 220S of another sub-pixel PXn adjacent to it in the first direction DR1. That is, different from the first electrode stem 210S, the second electrode stem 220S may extend in the first direction DR1 across the respective sub-pixels PXn. The second electrode stem 220S that is elongated (or extends) across the respective sub-pixels PXn may be connected to an outer part of the display area DA where the respective pixels PX or sub-pixels PXn are arranged or to an extension portion extended from the non-display area NDA in one direction.

The second electrode branch 220B may be disposed to face the first electrode branch 210B with a gap therebetween and may be terminated while being spaced apart from the first electrode stem 210S. The second electrode branch 220B may be connected to the second electrode stem 220S, and an end of the second electrode branch 220B in the extension direction (e.g., a distal end of the electrode branch 220B) may be disposed within the sub-pixel PXn while being spaced apart from the first electrode stem 210S.

The first electrode 210 and the second electrode 220 may be electrically connected to the conductive layer of a circuit element layer PAL (see, e.g., FIG. 4) of the display device 10 through contact openings (e.g., contact holes), including a first electrode contact hole CNTD and a second electrode contact hole CNTS, respectively. The second electrode contact hole CNTD is illustrated as being formed at every first electrode stem 210S of each sub-pixel PXn, while only one second electrode contact hole CNTS is illustrated as being formed at the single second electrode stem 220S, which is elongated across the respective sub-pixels PXn. However, the present disclosure is not limited thereto, and in some embodiments, the second electrode contact hole CNTS may be formed for each sub-pixel PXn.

The electrodes 210 and 220 may be electrically connected to the light emitting elements 300 and may receive a voltage applied thereto to allow the light emitting elements 300 to emit light in a specific wavelength band. Further, at least a part (or portion) of each of the electrodes 210 and 220 may be used to form an electric field within the sub-pixel PXn to align the light emitting elements 300.

In an embodiment, the first electrode 210 may be a pixel electrode which is separated for each sub-pixel PXn, and the second electrode 220 may be a common electrode connected along the respective sub-pixels PXn to be shared by them. One of the first and second electrodes 210 and 220 may be an anode electrode of the light emitting element 300, and the other of the first and second electrodes 210 and 220 may be a cathode electrode of the light emitting element 300.

The illustrated embodiment includes two first electrode branches 210B disposed in each sub-pixel PXn and one second electrode branch 220B disposed therebetween. However, the layout of the first and second electrode branches 210B and 220B may not be limited thereto. In some embodiments, the first electrode 210 and the second electrode 220 may have a shape without the electrode stems 210S and 220S and extending in the second direction DR2. Further, the first and second electrodes 210 and 220 may not necessarily have a shape extending in one direction and may have various layouts. For example, the first electrode 210 and the second electrode 220 may have a partially curved or bent shape, and one electrode may be disposed to surround (e.g., to extend around a periphery of) the other electrode. The layout and the shape of the first and second electrodes 210 and 220 may not be particularly limited as long as at least some portions thereof face each other with a gap therebetween, creating a space where the light emitting elements 300 may be disposed.

The external banks 430 may be disposed at the boundaries between the sub-pixels PXn. Each external bank 430 may extend in the second direction DR2 to be disposed at the boundary between the adjacent sub-pixels PXn that are arranged in (e.g., adjacent to each other in) the first direction DR1. The first electrode stems 210S may be terminated such that their respective ends are spaced apart from each other with the external banks 430 therebetween. However, the present disclosure is not limited thereto, and the external bank 430 may extend in the first direction DR1 to be disposed at the boundary between the adjacent sub-pixels PXn that are arranged in the second direction DR2. The external banks 430 may include the same material as the internal banks 410 and 420, to be described later, and the external and internal banks may be formed concurrently (or simultaneously) in one process.

The light emitting elements 300 may be disposed between the first electrode 210 and the second electrode 220. The light emitting element 300 may be electrically connected to the first electrode 210 at one end thereof and the second electrode 220 at the other end thereof. The light emitting element 300 may be electrically connected to each of the first electrode 210 and the second electrode 220 through the contact electrode 260.

The plurality of light emitting elements 300 may be spaced apart from each other and aligned substantially parallel to each other. The interval between the light emitting elements 300 is not particularly limited. In some embodiments, multiple light emitting elements 300 may be disposed adjacent to each other to form a group, and other light emitting elements 300 may be arranged while being spaced apart from each other at a regular distance to form another group. For example, the light emitting elements 300 may be arranged in different densities but they may be still aligned in one direction. Further, in an embodiment, the light emitting element 300 may have a shape extending in one direction, and the extension direction of the electrodes, for example, the first electrode branch 210B and the second electrode branch 220B, may be substantially perpendicular to the extension direction of the light emitting element 300. However, the present disclosure is not limited thereto, and the light emitting element 300 may be disposed diagonally with respect to the extension direction of the first electrode branch 210B and the second electrode branch 220B, not perpendicularly thereto.

The light emitting elements 300 according to one embodiment may have active layers 330 including different materials and, thus, may emit lights of different wavelength bands to the outside. The display device 10 according to one embodiment may include the light emitting elements 300 that emit light of different wavelength bands. The light emitting element 300 of the first sub-pixel PX1 may include the active layer 330 that emits a first light L1 having a central wavelength band of a first wavelength, the light emitting element 300 of the second sub-pixel PX2 may include the active layer 330 that emits a second light L2 having a central wavelength band of a second wavelength, and the light emitting element 300 of the third sub-pixel PX3 may include the active layer 330 that emits a third light L3 having a central wavelength band of a third wavelength.

Accordingly, the first light Ll may be emitted from the first sub-pixel PX1, the second light L2 may be emitted from the second sub-pixel PX2, and the third light L3 may be emitted from the third sub-pixel PX3. In some embodiments, the first light L1 may be blue light having a central wavelength band in a range of about 450 nm to about 495 nm, the second light L2 may be green light having a central wavelength band in a range of about 495 nm to about 570 nm, and the third light L3 may be red light having a central wavelength band in a range of about 620 nm to about 752 nm.

However, the present disclosure is not limited thereto. In some embodiments, the first sub-pixel PX1, the second sub-pixel PX2, and the third sub-pixel PX3 may include the light emitting elements 300 of the same type (e.g., having the same active layer 330) to emit light of substantially the same color.

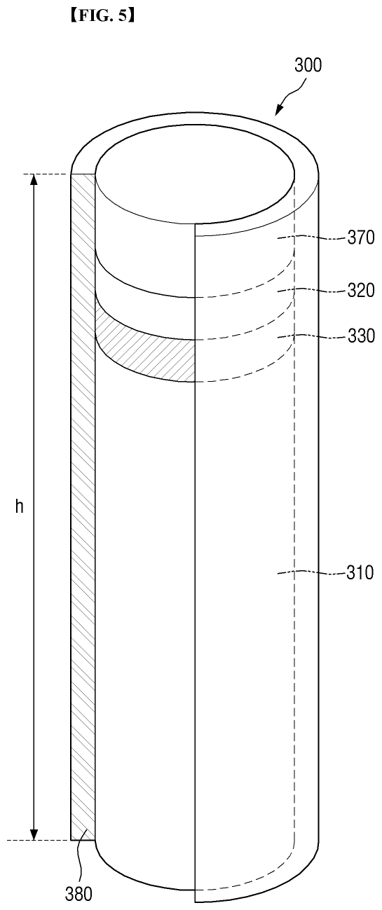

The light emitting element 300 according to one embodiment may include a semiconductor core and an insulating film 380 (see, e .g., FIG. 5) surrounding the semiconductor core. The semiconductor core may include a plurality of semiconductor layers 310 and 320 and an active layer 330 disposed therebetween. The light emitting element 300 may have one end electrically connected to the first electrode 210 and the other end electrically connected to the second electrode 220 to receive electric signals, and the light emitting element 300 that has received the electric signals may generate light in the active layer 330 and emit it to the outside. The insulating film 380 surrounding the semiconductor core of the light emitting element 300 may be disposed to surround (e.g., cover) at least the outer surface of the active layer 330 and protect it. The light emitting element 300 according to one embodiment may include the insulating film 380 having a thickness of a certain level or more sufficient to prevent the active layer 330 of the light emitting element 300 from being damaged during the manufacturing process of the light emitting element 300 and the manufacturing process of the display device 10 and to improve element reliability.

Further, the semiconductor core of the light emitting element 300 may further include an electrode layer 370 (see, e.g., FIG. 5) disposed on the second semiconductor layer 320, and the light emitting element 300 may be electrically connected to the first electrode 210 or the second electrode 220 through the electrode layer 370. The light emitting element 300 according to one embodiment may include the electrode layer 370 having a thickness of a certain level or more sufficient to prevent the electrode layer 370 of the light emitting element 300 from being removed during the manufacturing process of the light emitting element 300, thereby improving the element efficiency. A detailed description thereof will be given later.

The plurality of contact electrodes 260 may have a shape in which at least a partial region thereof extends in one direction. Each of the plurality of contact electrodes 260 may contact the light emitting element 300 and the electrodes 210 and 220, and the light emitting elements 300 may receive the electrical signals from the first electrode 210 and the second electrode 220 through the contact electrode 260.

The contact electrode 260 may include a first contact electrode 261 and a second contact electrode 262. The first contact electrode 261 and the second contact electrode 262 may be disposed on the first electrode branch 210B and the second electrode branch 220B, respectively.

The first contact electrode 261 may be disposed on the first electrode 210 or the first electrode branch 210B and may extend in the second direction DR2 to contact one end of the light emitting element 300. The second contact electrode 262 may be spaced apart from the first contact electrode 261 in the first direction DR1, may be disposed on the second electrode 220 or the second electrode branch 220B, and may extend in the second direction DR2 to contact the other end of the light emitting element 300. The first contact electrode 261 and the second contact electrode 262 may contact the first electrode 210 and the second electrode 220 exposed through openings of the second insulating layer 520. The light emitting element 300 may be electrically connected to the first electrode 210 and the second electrode 220 through the first contact electrode 261 and the second contact electrode 262.

In some embodiments, the widths of the first contact electrode 261 and the second contact electrode 262 measured in one direction may be respectively greater than the widths of the first electrode 210 and the second electrode 220 or the widths of the first electrode branch 210B and the second electrode branch 220B measured in the one direction. The first contact electrode 261 and the second contact electrode 262 may be disposed to cover the side portions of the first electrode 210 and the second electrode 220 or the side portions of the first electrode branch 210B and the second electrode branch 220B. However, the present disclosure is not limited thereto, and in some embodiments, the first contact electrode 261 and the second contact electrode 262 may be disposed to cover only one side portion of the first electrode branch 210B and the second electrode branch 220B.

Although the illustrated embodiment includes two first contact electrodes 261 and one second contact electrode 262 disposed in one sub-pixel PXn, the present disclosure is not limited thereto. The number of the first contact electrode 261 and the second contact electrode 262 may vary depending on the number of the first electrode(s) 210 and the second electrode(s) 220 disposed in each sub-pixel PXn or the number of the first electrode branch(es) 210B and the second electrode branch(es) 220B.

The display device 10 may further include the circuit element layer PAL positioned under the electrodes 210 and 220 and a plurality of insulating layers disposed thereon. Hereinafter, the stacked structure of the display device 10 will be described in more detail with reference to FIG. 4.

FIG. 4 is a cross-sectional view taken along the lines Xa-Xa′, Xb-Xb′ and Xc-Xc′ of FIG. 3.

FIG. 4 only shows a cross section of the first sub-pixel PX1, but the same description may be applied to other pixels PX or sub-pixels PXn. FIG. 4 shows a cross section passing through one end and the other end of the light emitting element 300 disposed in the first sub-pixel PX1.

Referring to FIG. 4 in conjunction with FIGS. 2 and 3, the display device 10 may include the circuit element layer PAL and an emission layer EML. The circuit element layer PAL may include a substrate 110, a buffer layer 115, a light blocking layer BML, conductive wires 191 and 192, first and second transistors 120 and 140, and the like, and the emission layer EML may include the above-described plurality of electrodes 210 and 220, the light emitting element 300, the plurality of contact electrodes 261 and 262, the plurality of insulating layers 510, 520, 530, 550, and the like.

The substrate 110 may be an insulating substrate. The substrate 110 may include (or may be made of) an insulating material, such as glass, quartz, or polymer resin. Further, the substrate 110 may be a rigid substrate, but may be, in other embodiments, a flexible substrate that can be bent, folded, or rolled.

The light blocking layer BML may be disposed on the substrate 110. The light blocking layer BML may include a first light blocking layer BML1 and a second light blocking layer BML2. The first light blocking layer BML1 may be electrically connected with a first source electrode 123 of the first transistor 120, to be described later. The second light blocking layer BML2 may be electrically connected with a second source electrode 143 of the second transistor 140.

The first light blocking layer BML1 and the second light blocking layer BML2 are arranged to overlap a first active material layer 126 of the first transistor 120 and a second active material layer 146 of the second transistor 140, respectively. The first and second light blocking layers BML1 and BML2 may include a material that blocks light and, thus, can prevent (or substantially prevent) light from reaching the first and second active material layers 126 and 146. For example, the first and second light blocking layers BML1 and BML2 may be formed of an opaque metal material that blocks light transmission. However, the present disclosure is not limited thereto, and in some embodiments, the light blocking layer BML may be omitted.

The buffer layer 115 is disposed on the light blocking layer BML and the substrate 110. The buffer layer 115 may be disposed to cover the entire surface of the substrate 110, including the light blocking layer BML. The buffer layer 115 can prevent diffusion of impurity ions, prevent penetration of moisture or external air, and perform a surface planarization function. Furthermore, the buffer layer 115 may insulate the light blocking layer BML and the first and second active material layers 126 and 146 from each other.

A semiconductor layer is disposed on the buffer layer 115. The semiconductor layer may include the first active material layer 126 of the first transistor 120, the second active material layer 146 of the second transistor 140, and an auxiliary layer 163. The semiconductor layer may include polycrystalline silicon, monocrystalline silicon, oxide semiconductor, and the like.

The first active material layer 126 may include a first doped region 126a, a second doped region 126b, and a first channel region 126c. The first channel region 126c may be disposed between the first doped region 126a and the second doped region 126b. The second active material layer 146 may include a third doped region 146a, a fourth doped region 146b, and a second channel region 146c. The second channel region 146c may be disposed between the third doped region 146a and the fourth doped region 146b. The first active material layer 126 and the second active material layer 146 may include polycrystalline silicon. The polycrystalline silicon may be formed by crystallizing amorphous silicon. Examples of the crystallizing method may include rapid thermal annealing (RTA), solid phase crystallization (SPC), excimer laser annealing (ELA), metal-induced lateral crystallization (MILC), and sequential lateral solidification (SLS) but are not limited thereto. As another example, the first active material layer 126 and the second active material layer 146 may include monocrystalline silicon, low-temperature polycrystalline silicon, amorphous silicon, or the like. The first doped region 126a, the second doped region 126b, the third doped region 146a, and the fourth doped region 146b may be areas of the first active material layer 126 and the second active material layer 146 doped with impurities. However, the present disclosure is not limited thereto.

The first active material layer 126 and the second active material layer 146 are not necessarily limited to the above-described embodiments. In an embodiment, the first active material layer 126 and the second active material layer 146 may include an oxide semiconductor. In such an embodiment, the first doped region 126a and the third doped region 146a may be a first conductive region, and the second doped region 126b and the fourth doped region 146b may be a second conductive region. When the first active material layer 126 and the second active material layer 146 include an oxide semiconductor, the oxide semiconductor may be an oxide semiconductor including (or containing) indium (In). In some embodiments, the oxide semiconductor may be indium tin oxide (ITO), indium zinc oxide (IZO), indium gallium oxide (IGO), indium zinc tin oxide (IZTO), indium gallium tin oxide (IGTO), indium gallium zinc tin oxide (IGZTO), or the like. However, the present disclosure is not limited thereto.

A first gate insulating film 150 is disposed on the semiconductor layer. The first gate insulating film 150 may be disposed to cover the entire surface of the buffer layer 115, including the semiconductor layer. The first gate insulating film 150 may act as a gate insulating film for the first and second transistors 120 and 140.

A first conductive layer is disposed on the first gate insulating film 150. The first conductive layer may include a first gate electrode 121 disposed on the first active material layer 126 of the first transistor 120, a second gate electrode 141 disposed on the second active material layer 146 of the second transistor 140, and a wiring pattern 161 disposed on the auxiliary layer 163 on the first gate insulating film 150. The first gate electrode 121 may overlap the first channel region 126c of the first active material layer 126, and the second gate electrode 141 may overlap the second channel region 146c of the second active material layer 146.

An interlayer insulating film 170 is disposed on the first conductive layer. The interlayer insulating film 170 may act as an insulating film between the first conductive layer and other layers disposed thereon. In addition, the interlayer insulating film 170 may include (or contain) an organic insulating material and may also perform a surface planarization function.

A second conductive layer is disposed on the interlayer insulating film 170. The second conductive layer includes the first source electrode 123 and the first drain electrode 124 of the first transistor 120, the second source electrode 143 and the second drain electrode 144 of the second transistor 140, and a power electrode 162 disposed on the wiring pattern 161.

The first source electrode 123 and the first drain electrode 124 may contact the first doped region 126a and the second doped region 126b of the first active material layer 126, respectively, via contact openings (e.g., contact holes) formed through the interlayer insulation film 170 and the first gate insulating film 150. The second source electrode 143 and the second drain electrode 144 may contact the third doped region 146a and the fourth doped region 146b of the second active material layer 146, respectively, via contact openings (e.g., contact holes) formed through the interlayer insulation film 170 and the first gate insulating film 150. Further, the first source electrode 123 and the second source electrode 143 may be electrically connected to the first light blocking layer BML1 and the second light blocking layer BML2, respectively, via other contact openings (e.g., other contact holes).

A passivation film 180 may be disposed on the second conductive layer. The passivation film 180 may be disposed to cover the second conductive layer and may be disposed on the entire interlayer insulating film 170. For example, the passivation film 180 may be disposed to cover the first source electrode 123, the first drain electrode 124, the second source electrode 143, and the second drain electrode 144.

A conductive wiring layer may be disposed on the passivation film 180. The conductive wiring layer may include the first conductive wire 191 and the second conductive wire 192, and they may be electrically connected to the first source electrode 123 of the first transistor 120 and the power electrode 162, respectively.

The conductive wiring layer may also be electrically connected to the first electrode 210 and the second electrode 220 of the emission layer EML and may transmit electrical signals applied from the first transistor 120 and the power electrode 162 to the electrodes 210 and 220.

A first insulating layer 510 is disposed on the conductive wiring layer. The first insulating layer 510 includes (or contains) an organic insulating material and may perform a surface planarization function.

The plurality of internal banks 410 and 420, the external bank 430 (see, e.g., FIG. 4), the plurality of electrodes 210 and 220, and the light emitting element 300 may be disposed on the first insulating layer 510.

As described above, the external bank 430 may extend in the first direction DR1 or the second direction DR2 to be disposed at the boundary between the sub-pixels PXn. For example, the external bank 430 may delimit the boundary of each sub-pixel PXn.

The external banks 430 may prevent ink from going over the boundaries of the sub-pixels PXn when the ink is deposited (e.g., jetted) in which the light emitting elements 300 are dispersed using an inkjet printing device in the manufacture of the display device 10. The external bank 430 may separate inks in which different light emitting elements 300 are dispersed for different sub-pixels PXn so they are not mixed with each other. However, the present disclosure is not limited thereto.

The plurality of internal banks 410 and 420 may be disposed to be spaced apart from each other in each sub-pixel PXn. The multiple internal banks 410 and 420 may include the first internal bank 410 and the second internal bank 420 disposed adjacent to the center of each sub-pixel PXn.

The first internal back 410 and the second internal bank 420 are disposed to face each other. The first electrode 210 may be disposed on the first internal bank 410, and the second electrode 220 may be disposed on the second internal bank 420. As shown in FIGS. 3 and 4, the first electrode branch 210B is disposed on the first internal bank 410, and the second electrode branch 220B is disposed on the second internal bank 420.

Similar to the first electrode 210 and the second electrode 220, the first internal bank 410 and the second internal bank 420 may be disposed to extend in the second direction DR2 in each sub-pixel PXn. The first internal bank 410 and the second internal bank 420 may extend in the second direction DR2 toward the sub-pixels PXn adjacent thereto in the second direction DR2. However, the present disclosure is not limited thereto, and the first internal bank 410 and the second internal bank 420 may be disposed in each of the sub-pixels PXn separately, forming a pattern on (or over) the entire surface of the display device 10.

Each of the first internal bank 410 and the second internal bank 420 may have a structure with at least a part thereof protruding above the first insulating layer 510. Each of the first internal bank 410 and the second internal bank 420 may protrude above the plane on which the light emitting element 300 is disposed, and at least a part of this protruding portion may have a slope. The shape of the protruding portions of the first and second internal banks 410 and 420 is not particularly limited. Because the internal banks 410 and 420 protrude with respect to the first insulating layer 510 and have inclined side surfaces, light emitted from the light emitting element 300 may be reflected by the inclined side surfaces of the internal banks 410 and 420. As will be described later, when the electrodes 210 and 220 disposed on the internal banks 410 and 420 include a material having high reflectivity, light emitted from the light emitting element 300 may be reflected by the electrodes 210 and 220 positioned on the inclined side surfaces of the internal banks 410 and 420 and travel in an upward direction of the first insulating layer 510.

For example, the external bank 430 may delimit adjacent sub-pixels PXn and may prevent ink from overflowing to an adjacent sub-pixels PXn in an inkjet process, and the internal banks 410 and 420 may have a protruding structure in each sub-pixel PXn and act as a reflective partition wall for reflecting light emitted from the light emitting element 300 in the upward direction of the first insulating layer 510. However, the present disclosure is not limited thereto. The plurality of internal banks 410 and 420 and external banks 430 may include, but are not limited to, polyimide (PI).

The plurality of electrodes 210 and 220 may be disposed on the first insulating layer 510 and the internal banks 410 and 420, respectively. As stated above, the electrodes 210 and 220 include the electrode stems 210S and 220S and the electrode branches 210B and 220B, respectively. The line Xa-Xa′ of FIG. 3 crosses the first electrode stem 210S, the line Xb-Xb′ of FIG. 3 crosses the first and second electrode branches 210B and 220B, and the line Xc-Xc′ of FIG. 3 extends along the second electrode stem 220S. The first electrode 210 disposed in the area Xa-Xa′ in FIG. 4 can be understood to be the first electrode stem 210S; the first electrode 210 and the second electrode 220 disposed in the area Xb-Xb′ in FIG. 4 can be understood to be the first electrode branch 210B and the second electrode branch 220B, respectively; and the second electrode 220 disposed in the area Xc-Xc′ in FIG. 4 can be understood to be the second electrode stem 220S. The electrode stems 210S and the electrode branch 210B may from (or may constitute) the first electrode 210, and the electrode stem 220S and the electrode branch 220B may form (or may constitute) the second electrode 220.

Some areas of the first and second electrodes 210 and 220 may be disposed on the first insulating layer 510 and some other areas thereof may be disposed on the first and second internal banks 410 and 420, respectively. For example, the widths of the first electrode 210 and the second electrode 220 may be greater than the widths of the internal banks 410 and 420. Parts of the bottom surfaces of the first electrode 210 and the second electrode 220 may contact the first insulating layer 510, and other parts thereof may contact the internal banks 410 and 420.

The first electrode stem 210S of the first electrode 210 and the second electrode stem 220S of the second electrode 220, which extend in the first direction DR1, may partially overlap the first internal bank 410 and the second internal bank 420, respectively. However, the present disclosure is not limited thereto, and the first electrode stem 210S and the second electrode stem 220S may not overlap (e.g., may be offset from) the first internal bank 410 and the second internal bank 420, respectively.

The first electrode contact hole CNTD may be formed in the first electrode stem 210S of the first electrode 210 to penetrate the first insulating layer 510 and expose a part of the first conductive wire 191. The first electrode 210 may contact the first conductive wire 191 through the first electrode contact hole CNTD, and the first electrode 210 may be electrically connected to the first source electrode 123 of the first transistor 120 to receive an electrical signal.

The second electrode contact hole CNTS may be formed in the second electrode stem 220S of the second electrode 220 to penetrate the first insulating layer 510 and expose a part of the second conductive wire 192. The second electrode 220 may contact the second conductive wire 192 through the second electrode contact hole CNTS, and the second electrode 220 may be electrically connected to the power electrode 162 to receive an electrical signal.

Some areas of the first electrode 210 and the second electrode 220, for example, the first electrode branch 210B and the second electrode branch 220B, may be disposed to cover the first internal bank 410 and the second internal bank 420, respectively. The first electrode 210 and the second electrode 220 may face each other with a gap therebetween, and the plurality of light emitting elements 300 may be disposed therebetween.

Each of the electrodes 210 and 220 may include a transparent conductive material. For example, each of the electrodes 210 and 220 may include a material, such as indium tin oxide (ITO), indium zinc oxide (IZO), and indium tin zinc oxide (ITZO), but they are not limited thereto. In some embodiments, each of the electrodes 210 and 220 may include a conductive material having high reflectivity. For example, each of the electrodes 210 and 220 may include, as a material having high reflectivity, a metal, such as silver (Ag), copper (Cu), or aluminum (Al). In such an embodiment, light incident to each of the electrodes 210 and 220 may be reflected to be radiated in an upward direction from each sub-pixel PXn.

Further, each of the electrodes 210 and 220 may have a structure in which at least one transparent conductive material and at least one metal layer having high reflectivity are stacked or may be formed as one layer including them. In an embodiment, each of the electrodes 210 and 220 may have a stacked structure of ITO/silver (Ag)/ITO/IZO or may include (or may be made of) an alloy including aluminum (Al), nickel (Ni), and/or lanthanum (La). However, the present disclosure is not limited thereto.

The second insulating layer 520 is disposed on the first insulating layer 510, the first electrode 210, and the second electrode 220. The second insulating layer 520 is disposed to partially cover the first electrode 210 and the second electrode 220. The second insulating layer 520 may be disposed to cover most of the top surfaces of the first electrode 210 and the second electrode 220, and the openings exposing parts of the first electrode 210 and the second electrode 220 may be formed in the second insulating layer 520. The openings in the second insulating layer 520 may be positioned to expose the relatively flat top surfaces of the first electrode 210 and the second electrode 220.

In an embodiment, the second insulating layer 520 may be formed to have a step such that a portion of the top surface thereof is recessed between the first electrode 210 and the second electrode 220. In some embodiments, the second insulating layer 520 may include (or contain) an inorganic insulating material, and a part of the top surface of the second insulating layer 520 disposed to cover the first electrode 210 and the second electrode 220 may be recessed by the step formed by the electrodes 210 and 220. The light emitting element 300 disposed on the second insulating layer 520 between the first electrode 210 and the second electrode 220 may form an empty space with respect to the recessed top surface of the second insulating layer 520. The light emitting element 300 may be disposed partially spaced apart from the top surface of the second insulating layer 520 with a space (e.g., a clearance) therebetween, and this space may be filled with a material forming the third insulating layer 530, to be described later.

However, the present disclosure is not limited thereto. The second insulating layer 520 may include a flat top surface with the light emitting element 300 disposed thereon. The top surface may extend in one direction toward the first electrode 210 and the second electrode 220 and may be terminated on inclined side surfaces of the first electrode 210 and the second electrode 220. For example, the second insulating layer 520 may be disposed in an area where the electrodes 210 and 220 overlap the inclined side surfaces of the first internal bank 410 and the second internal bank 420, respectively. The contact electrode 260 may contact the exposed areas of the first and second electrodes 210 and 220 and may smoothly contact an end of the light emitting element 300 on the flat top surface of the second insulating layer 520.

The second insulating layer 520 may protect the first electrode 210 and the second electrode 220 while insulating them from each other. Further, the light emitting element 300 disposed on the second insulating layer 520 may not be damaged by direct contact with other members. However, the shape and structure of the second insulating layer 520 are not limited thereto.

The light emitting element 300 may be disposed on the second insulating layer 520 between the electrodes 210 and 220. For example, at least one light emitting element 300 may be disposed on the second insulating layer 520 disposed between the electrode branches 210B and 220B. However, the present disclosure is not limited thereto, and at least some of the light emitting elements 300 disposed in each sub-pixel PXn may be in a region other than the region between the electrode branches 210B and 220B. Further, the light emitting element 300 may be disposed such that some areas thereof overlap the electrodes 210 and 220. The light emitting element 300 may be disposed on ends where the first electrode branch 210B and the second electrode branch 220B face each other.

In the light emitting element 300, a plurality of layers may be disposed in a direction parallel to the first insulating layer 510. The light emitting element 300 according to one embodiment may have a shape extending in one direction and may have a structure in which a plurality of semiconductor layers are sequentially arranged in one direction. In the light emitting element 300, the first semiconductor layer 310, the active layer 330, the second semiconductor layer 320, and the electrode layer 370 may be sequentially disposed along one direction, and the outer surfaces thereof may be surrounded (e.g., covered) by the insulating film 380. The light emitting element 300 may be disposed in the display device 10 such that one extension direction is parallel to the first insulating layer 510, and the plurality of semiconductor layers included in the light emitting element 300 may be sequentially disposed along the direction parallel to the top surface of the first insulating layer 510. However, the present disclosure is not limited thereto. In some embodiments, when the light emitting element 300 has a different structure, a plurality of layers may be arranged in a direction perpendicular to the first insulating layer 510.

Further, one end of the light emitting element 300 may contact the first contact electrode 261, and the other end thereof may contact the second contact electrode 262. According to one embodiment, because the end surfaces of the light emitting element 300 in the direction in which it extends are exposed without the insulating film 380 formed thereon, the light emitting element 300 may contact the first contact electrode 261 and the second contact electrode 262 at the exposed regions. However, the present disclosure is not limited thereto. In some embodiments, in the light emitting element 300, at least some regions of the insulating film 380 may be removed (or omitted), and the insulating film 380 may be removed (or formed) to partially expose both end side surfaces of the light emitting element 300. During the manufacturing process of the display device 10, in the step of forming the third insulating layer 530 covering the outer surface of the light emitting element 300, the insulating film 380 may be partially removed. The exposed side surfaces of the light emitting element 300 may contact the first contact electrode 261 and the second contact electrode 262. However, the present disclosure is not limited thereto.

The third insulating layer 530 may be partially disposed on the light emitting element 300 disposed between the first electrode 210 and the second electrode 220. The third insulating layer 530 may be disposed to partially surround the outer surface of the light emitting element 300 to protect the light emitting element 300 and may fix the light emitting element 300 during the manufacturing process of the display device 10. According to one embodiment, the third insulating layer 530 may be disposed on the light emitting element 300 and may expose one end and the other end of the light emitting element 300. The exposed ends (e.g., the one end and the other end) of the light emitting element 300 may contact the contact electrode 260 so that electrical signals may be received from the electrodes 210 and 220. The shape of the third insulating layer 530 may be formed by a patterning process using a material forming the third insulating layer 530 using a conventional mask process. The mask for forming the third insulating layer 530 may have a width smaller than the length of the light emitting element 300, and the material forming the third insulating layer 530 may be patterned such that both ends of the light emitting element 300 are exposed. However, the present disclosure is not limited thereto.

Further, in an embodiment, a portion of the material of the third insulating layer 530 may be disposed between the bottom surface of the light emitting element 300 and the second insulating layer 520. The third insulating layer 530 may be formed to fill a space between the second insulating layer 520 and the light emitting element 300 formed during the manufacturing process of the display device 10. Accordingly, the third insulating layer 530 may be formed to surround the outer surface of the light emitting element 300. However, the present disclosure is not limited thereto.

The third insulating layer 530 may extend in the second direction DR2 between the first electrode branch 210B and the second electrode branch 220B in a plan view. For example, the third insulating layer 530 may have an island shape or a linear shape on the first insulating layer 510 in a plan view.

The first contact electrode 261 is disposed on the electrode 210 and the third insulating layer 530, and the second contact electrode 262 is disposed on the second electrode 220 and the third insulating layer 530. The third insulating layer 530 may be disposed between the first contact electrode 261 and the second contact electrode 262 and may insulate them from each other to prevent direct contact between the first contact electrode 261 and the second contact electrode 262.

As described above, the first contact electrode 261 and the second contact electrode 262 may contact at least one end of the light emitting element 300, and the first contact electrode 261 and the second contact electrode 262 may be electrically connected to the first electrode 210 or the second electrode 220 to receive an electrical signal.

The first contact electrode 261 may contact the exposed area of the first electrode 210 on the first internal bank 410, and the second contact electrode 262 may contact the exposed area of the second electrode 220 on the second internal bank 420. The first contact electrode 261 and the second contact electrode 262 may respectively transmit electrical signals transmitted from the electrodes 210 and 220 to the light emitting element 300.

The contact electrode 260 may include a conductive material. For example, they may include ITO, IZO, ITZO, aluminum (Al), or the like. However, the present disclosure is not limited thereto.

A passivation layer 550 may be disposed on the contact electrode 260 and the third insulating layer 530. The passivation layer 550 may protect the members disposed on the first insulating layer 510 from the external environment.

Each of the first insulating layer 510, the second insulating layer 520, the third insulating layer 530, and the passivation layer 550 described above may include an inorganic insulating material or an organic insulating material. In an embodiment, the first insulating layer 510, the second insulating layer 520, the third insulating layer 530, and the passivation layer 550 may include an inorganic insulating material, such as silicon oxide (SiOₓ), silicon nitride (SiNₓ), silicon oxynitride (SiOₓN_{y}), aluminum oxide (AlₓO_{y}), aluminum nitride (AIN), and the like. The first insulating layer 510, the second insulating layer 520, the third insulating layer 530, and the passivation layer 550 may include an organic insulating material, such as acrylic resin, epoxy resin, phenolic resin, polyamide resin, polyimide resin, unsaturated polyester resin, polyphenylene resin, polyphenylene sulfide resin, benzocyclobutene, cardo resin, siloxane resin, silsesquioxane resin, polymethylmethacrylate, polycarbonate, and polymethylmethacrylate-polycarbonate synthetic resin. However, the present disclosure is not limited thereto.

The display device 10 according to one embodiment may include the light emitting element 300 including the electrode layer 370 and the insulating film 380, each having a thickness of a certain level or more. According to one embodiment, the active layer 330 of the light emitting element 300 may not be damaged and/or the electrode layer 370 may not be removed during the manufacturing process of the light emitting element 300 and the manufacturing process of the display device 10, and the light emitting element 300 may exhibit improved luminous efficiency and luminous reliability. Hereinafter, the light emitting element 300 according to embodiments of the present disclosure will be described in detail with reference to other drawings.

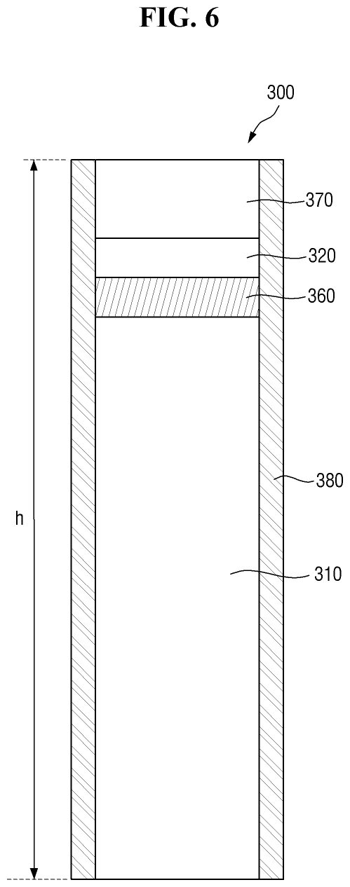

FIG. 5 is a schematic diagram of a light emitting element according to one embodiment. FIG. 6 is a schematic cross-sectional view of a light emitting element according to one embodiment.

A light emitting element 300 may be a light emitting diode. For example, the light emitting element 300 may be an inorganic light emitting diode that has a micrometer or nanometer size and including (or made of) an inorganic material. The inorganic light emitting diode may be aligned between two electrodes having polarity when an electric field is formed in a specific direction between the two opposing electrodes. The light emitting element 300 may be aligned between the two electrodes by the electric field generated between the electrodes.

The light emitting element 300 according to one embodiment may have a shape extending in one direction. The light emitting element 300 may have a shape of a rod, wire, tube, or the like. In an embodiment, the light emitting element 300 may have a cylindrical or rod shape. However, the shape of the light emitting element 300 is not limited thereto, and the light emitting element 300 may have a polygonal prism shape, such as a regular cube, a rectangular parallelepiped, and a hexagonal prism, or may have various suitable shapes, such as a shape extending in one direction and having partially inclined outer surface. A plurality of semiconductors included in the light emitting element 300, to be described later, may have a structure in which they are sequentially arranged or stacked along the one direction.

The light emitting element 300 may include a semiconductor layer doped with any conductivity type (e.g., p-type or n-type) impurities. The semiconductor layer may emit light of a specific wavelength band by receiving an electrical signal applied from an external power source.

The light emitting element 300 according to one embodiment may emit light of a specific wavelength band. In an embodiment, the active layer 330 may emit blue light having a central wavelength band ranging from about 450 nm to about 495 nm. However, it should be understood that the central wavelength band of blue light is not limited to the above-mentioned range but includes all wavelength ranges that can be recognized as blue in the pertinent art. Further, the light emitted from the active layer 330 of the light emitting element 300 may not be limited thereto and may be emit green light having a central wavelength band ranging from about 495 nm to about 570 nm or may emit red light having a central wavelength band ranging from about 620 nm to about 750 nm. Hereinafter, the description will be provided on the assumption that the light emitting element 300 emits blue light as an example.

Referring to FIGS. 5 and 6, the light emitting element 300 may include the semiconductor core and the insulating film 380 surrounding (e.g., extending around or covering) the semiconductor core, and the semiconductor core of the light emitting element 300 may include the first semiconductor layer 310, the second semiconductor layer 320, and the active layer 330. Further, the light emitting element 300 according to one embodiment may further include the electrode layer 370 disposed on one surface of the first semiconductor layer 310 or the second semiconductor layer 320.

The first semiconductor layer 310 may be an n-type semiconductor. For example, when the light emitting element 300 emits light of a blue wavelength band, the first semiconductor layer 310 may include a semiconductor material having a chemical formula of AlₓGa_{y}In_{1-x-y}N (0≤x+y≤1). For example, the semiconductor material may be any one or more of n-type doped AlGaInN, GaN, AlGaN, InGaN, AlN, and InN. The first semiconductor layer 310 may be doped with an n-type dopant. For example, the n-type dopant may be Si, Ge, Sn, or the like. In an embodiment, the first semiconductor layer 310 may be n-GaN doped with n-type Si. The length of the first semiconductor layer 310 may be in a range of about 1.5 μm to about 5 μm but is not limited thereto.

The second semiconductor layer 320 is disposed on the active layer 330. The second semiconductor layer 320 may be a p-type semiconductor. For example, when the light emitting element 300 emits light of a blue or green wavelength band, the second semiconductor layer 320 may include a semiconductor material having a chemical formula of AlₓGa_{y}In_{1-x-y}N (0≤x≤1, 0≤y≤1, 0≤x+y≤1). For example, the second semiconductor layer 320 may be any one or more of p-type doped AlGaInN, GaN, AIGaN, InGaN, AIN and InN. The second semiconductor layer 320 may be doped with a p-type dopant. For example, the p-type dopant may be Mg, Zn, Ca, Se, Ba, or the like. In an embodiment, the second semiconductor layer 320 may be p-GaN doped with p-type Mg. The length of the second semiconductor layer 320 may be in a range of about 0.05 μm to about 0.10 μm but is not limited thereto.

Although the first semiconductor layer 310 and the second semiconductor layer 320 in the illustrated embodiment are a single layer, the present disclosure is not limited thereto. According to some embodiments, depending on the material of the active layer 330, the first semiconductor layer 310 and the second semiconductor layer 320 may have a greater number of layers, such as a cladding layer or a tensile strain barrier reducing (TSBR) layer. A description thereof will be given later with reference to other drawings.

The active layer 330 is disposed between the first semiconductor layer 310 and the second semiconductor layer 320. The active layer 330 may include a material having a single or multiple quantum well structure. When the active layer 330 includes a material having a multiple quantum well structure, a plurality of quantum layers and well layers may be alternately stacked. The active layer 330 may emit light by the coupling of electron-hole pairs according to an electrical signal applied through the first semiconductor layer 310 and the second semiconductor layer 320. For example, when the active layer 330 emits light of a blue wavelength band, a material such as AIGaN or AlGaInN may be included. When the active layer 330 has a multiple quantum well structure in which quantum layers and well layers are alternately stacked in, the quantum layer may include a material, such as AIGaN or AlGaInN, and the well layer may include a material, such as GaN or AlInN. In an embodiment, as described above, the active layer 330 includes AlGaInN as a quantum layer and AlInN as a well layer, and the active layer 330 may emit blue light having a central wavelength band of 450 nm to 495 nm.

However, the present disclosure is not limited thereto, and the active layer 330 may have a structure in which semiconductor materials having large band gap energy and semiconductor materials having small band gap energy are alternately stacked, and the semiconductor materials may include other group III to V semiconductor materials according to the wavelength band of the emitted light. The light emitted by the active layer 330 is not limited to light of a blue wavelength band, and the active layer 330 may also emit light of a red or green wavelength band in different embodiments. The length of the active layer 330 may be in a range of about 0.05 μm to about 0.10 μm, but it is not limited thereto.

Light emitted from the active layer 330 may be emitted to both side surfaces as well as the outer surface of the light emitting element 300 in a longitudinal direction. The directionality of the light emitted from the active layer 330 is not limited to one direction.

The electrode layer 370 may be an ohmic contact electrode. However, the present disclosure is not limited thereto, and electrode layer 370 may be a Schottky contact electrode. The light emitting element 300 may include at least one electrode layer 370. Although FIG. 6 illustrates that the light emitting element 300 includes one electrode layer 370, the present disclosure is not limited thereto. In some embodiments, the light emitting element 300 may include a greater number of electrode layers 370, or the electrode layer 370 may be omitted. The following description of the light emitting element 300 may be equally applied even when the number of electrode layers 370 is different or further includes other structures.

In the display device 10 according to an embodiment, when the light emitting element 300 is electrically connected to an electrode or a contact electrode, the electrode layer 370 may reduce the resistance between the light emitting element 300 and the electrode or contact electrode. The electrode layer 370 may include a conductive metal. For example, the electrode layer 370 may include at least one of aluminum (Al), titanium (Ti), indium (In), gold (Au), silver (Ag), indium tin oxide (ITO), indium zinc oxide (IZO), or indium tin zinc oxide (ITZO). Further, the electrode layer 370 may include an n-type or p-type doped semiconductor material. The electrode layer 370 may include the same material or different materials, but it is not limited thereto.

In the light emitting element 300, the electrode layer 370 may be partially etched during the manufacturing process. As will be described later, in the process of forming the insulating film 380, the electrode layer 370 may be partially etched to have a thickness smaller than an initial thickness. In the light emitting element 300, the electrode layer 370 may have a thickness of a certain level or more to prevent the electrode layer 370 from being etched and removed during the above process. In the light emitting element 300 according to one embodiment, the thickness of the electrode layer 370 may be within a range of about 20 nm to about 200 nm or, in one embodiment, within a range of about 100 nm to about 200 nm. When the electrode layer 370 has a thickness smaller than about 20 nm, the electrode layer 370 may be etched and removed in the process of forming the insulating film 380 or contact failure with the second semiconductor layer 320 may occur. And when the thickness of the electrode layer 370 is about 200 nm or more, the light generated in the active layer 330 may be absorbed by the electrode layer 370 so that the optical characteristics of the light emitting element 300 may deteriorate. Accordingly, the electrode layer 370 of the light emitting element 300 may have a thickness of about 20 nm or more, and in some embodiments, may be within a range of about 100 nm to about 200 nm.

In the light emitting element 300, the light generated in the active layer 330 may be emitted through both end surfaces (e.g., the top surface of the electrode layer 370 or the bottom surface of the first semiconductor layer 310). The transmittance of the light generated in the active layer 330 may vary depending on the thickness of the electrode layer 370. However, the light emitting element 300 according to one embodiment may include the electrode layer 370 having a thickness within the above-described range and have the transmittance of a certain level or more. For example, when the active layer 330 generates blue light having a central wavelength band of about 450 nm, the electrode layer 370 may have the transmittance of 65% or more or 70% or more with respect to the light having the central wavelength band of about 450 nm. However, the present disclosure is not limited thereto.

Furthermore, in the light emitting element 300, because the electrode layer 370 has the thickness within the above-described range, the change in the transmittance with respect to the thickness may be reduced or minimized. For example, when the electrode layer 370 has a thickness of about 20 nm to about 200 nm, or about 100 nm to about 200 nm, the change in the transmittance with respect to the light having the central wavelength band of about 450 nm may be about 3% or about 1%. Accordingly, in the light emitting element 300, the thickness of the electrode layer 370 may be controlled to prevent the electrode layer 370 from being removed during the manufacturing process of the display device 10, and the emission characteristics and the element efficiency may be improved due to it having the transmittance of a certain level or more.

Further, in some embodiments, the electrode layer 370 of the light emitting element 300 may have a thickness greater than that of the second semiconductor layer 320. Due to the larger thickness of the electrode layer 370, the electrode layer 370 may smoothly contact the second semiconductor layer 320 or the first contact electrode 261. In some embodiments, the electrode layer 370 of the light emitting element 300 may be formed to be thicker than the second semiconductor layer 320. However, the present disclosure is not limited thereto.

The insulating film 380 is disposed to surround the outer surfaces of the above-described semiconductor core and electrode layer. In an embodiment, the insulating film 380 may be arranged to surround at least the outer surface of the active layer 330 and extend along the extension direction of the light emitting element 300. The insulating film 380 may protect the members. For example, the insulating film 380 may be formed to surround side surfaces of the members while exposing both ends of the light emitting element 300 in the longitudinal direction.

Although the insulating film 380 extends in the longitudinal direction of the light emitting element 300 to cover a region from the first semiconductor layer 310 to the side surface of the electrode layer 370 in the illustrated embodiment, the present disclosure is not limited thereto. The insulating film 380 may cover only the outer surfaces of some semiconductor layers, including the active layer 330, or may cover only a part of the outer surface of the electrode layer 370 to partially expose the outer surface of each electrode layer 370. Further, in a cross-sectional view, the insulating film 380 may have a top surface, which is rounded in a region adjacent to at least one end of the light emitting element 300.

The insulating film 380 may include materials having insulating properties, for example, silicon oxide (SiOₓ), silicon nitride (SiNₓ), silicon oxynitride (SiOₓN_{y}), aluminum nitride (AlN), aluminum oxide (AₓO_{y}), and the like. Accordingly, an electrical short circuit that may occur when the active layer 330 directly contacts the electrode through which the electrical signal is transmitted to the light emitting element 300 may be prevented. In addition, because the insulating film 380 protects the outer surface of the light emitting element 300 including the active layer 330, degradation in luminous efficiency may be avoided.

Further, in some embodiments, the insulating film 380 may have an outer surface which is surface-treated. When the display device 10 is manufactured, the light emitting elements 300 may be aligned by being sprayed on the electrodes in a state of being dispersed in an ink (e.g., a predetermined ink). The surface of the insulating film 380 may be treated to have a hydrophobic property or hydrophilic property to keep the light emitting element 300 in the dispersed state without being aggregated with other neighboring light emitting elements 300 in the ink.

The light emitting element 300 may have a length in a range of about 1 μm to about 10 μm or about 2 μm to about 6 μm, and in one embodiment, in a range of about 3 μm to about 5 μm. Further, a diameter of the light emitting element 300 may be in a range of about 300 nm to about 700 nm, and an aspect ratio of the light emitting element 300 may be about 1.2 to about 100. However, the present disclosure is not limited thereto, and the plurality of light emitting elements 300 included in the display device 10 may have different diameters according to a difference in composition of the active layer 330. In one embodiment, the diameter of the light emitting element 300 may be in a range of about 500 nm.

The insulating film 380 may include at least the active layer 330 to protect the semiconductor core of the light emitting element 300. As described above, during the manufacturing process of the light emitting element 300 and the manufacturing process of the display device 10, the insulating film 380 may be partially etched to have a reduced thickness. When the insulating film 380 has the reduced thickness, the insulating film 380 may be etched and removed during the manufacturing process, or the semiconductor core, such as, the active layer 330, may be damaged. The insulating film 380 of the light emitting element 300 according to one embodiment may have a thickness of a certain level or more.

In the light emitting element 300 according to one embodiment, the insulating film 380 may have a thickness within a range of about 10 nm to about 1.0 μm, within a range of about 20 nm to about 80 nm, or, in one embodiment, within a range of about 60 nm to about 80 nm. The insulating film 380 may have the thickness within the above-described range and may be disposed to surround at least the outer surface of the active layer 330. Accordingly, even if the insulating film 380 is partially etched during the manufacturing process of the light emitting element 300 and the manufacturing process of the display device 10, the insulating film 380 may remain on the outer surface of the active layer 330 and protect it. Although the insulating film 380 is disposed to surround the entire outer surface of the semiconductor core including the active layer 330 and is disposed to surround the side surfaces of the first semiconductor layer 310 and the electrode layer 370 in the illustrated embodiment, the present disclosure is not limited thereto. In the light emitting element 300, the insulating film 380 may not be disposed and the outer surface of the semiconductor core may be partially exposed.

Because the insulating film 380 has the thickness within the above-described range, the diameter of the semiconductor core and the thickness of the insulating film 380 may have a relationship in the light emitting element 300. For example, in the light emitting element 300, the thickness of the insulating film 380 may be within the range of about 10% to about 16% of the diameter of the semiconductor core. When the insulating film 380 has the thickness within the above-described range, the semiconductor core, including the active layer 330, may be protected.

Further, in some embodiments, the insulating film 380 may be disposed along the outer surface of the semiconductor core but may not have a uniform thickness. The insulating film 380 may have different thicknesses on the outer surfaces of the first semiconductor layer 310, the active layer 330, the second semiconductor layer 320, and the electrode layer 370. The different thicknesses may be because the insulating film 380 is etched during the manufacturing process of the light emitting element 300 or is partially etched after the light emitting element 300 is disposed on the display device 10 to have different thicknesses depending on positions.

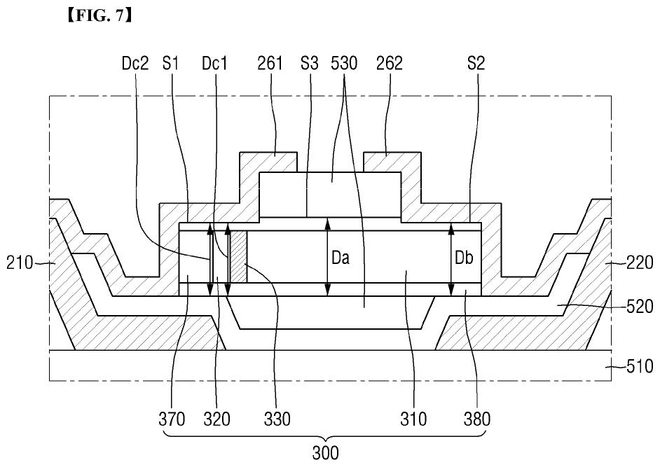

FIG. 7 is an enlarged view of the area QA of FIG. 4.

FIG. 7 is an enlarged cross-sectional view illustrating the light emitting element 300 disposed between the first electrode 210 and the second electrode 220 in the display device 10. Referring to FIG. 7, the light emitting element 300 may be disposed on the second insulating layer 520 between the first electrode 210 and the second electrode 220. The light emitting element 300 may include, on the outer surface of the insulating film 380, one side surface that is a lower surface and the other side surface that is an upper surface in a cross-sectional view. The one side surface may contact the second insulating layer 520 and the third insulating layer 530 disposed on the lower side of the light emitting element 300 and the other side surface may contact the insulating layer 530 and the contact electrode 260 disposed on the upper side of the light emitting element 300.

The one side surface, that is, the lower surface, of the light emitting element 300 may contact the second insulating layer 520 and may contact the third insulating layer 530 in the space formed by partially recessing the second insulating layer 520 and filled with the third insulating layer 530. The one side surface, that is, the lower surface, of the light emitting element 300 in a cross-sectional view may not be etched during the manufacturing process of the display device 10. Accordingly, the contact surface between the second insulating layer 520 and the third insulating layer 530 may form a flat surface.

On the other hand, in the light emitting element 300, the other side surface, that is, the upper surface in a cross-sectional view, may be partially etched in the etching process performed before the process of forming the contact electrode 260.

On the other side surface, the insulating film 380 may be etched in the region contacting the contact electrode 260 except (other than) the portion contacting the third insulating layer 530. The display device 10 according to one embodiment may include the region in which the thickness of the insulating film 380 of the light emitting element 300 is partially different. The other side surface may include a first surface (e.g., a first surface portion) 51 in contact with the first contact electrode 261, a second surface (e.g., a second surface portion) S2 in contact with the second contact electrode 262, and a third surface (e.g., a third surface portion) S3 in contact with the third insulating layer 530. The first surface S1 and the second surface S2 may be partially etched before the process of forming the contact electrode 260 so that the insulating film 380 may have a relatively small thickness at these portions, and the third surface S3 may contact the third insulating layer 530 so that the insulating film 380 may not be etched at this portion. Accordingly, the insulating film 380 may have a smaller thickness in the regions corresponding to the first surface S1 and the second surface S2 than in the region corresponding to the third surface S3.

The thickness of the insulating film 380 of the light emitting element 300 may be the thickness of the region where the third surface S3 is positioned. For example, the light emitting element 300 of the display device 10 may have a thickness within the range of about 60 nm to about 80 nm in the region of the insulating film 380 where the third surface S3 is positioned (e.g., in the region in contact with the third insulating layer 530). On the other hand, the thickness of the light emitting element 300 may be within the range of about 40 nm to about 60 nm in the regions where the first surface 51 and the second surface S2 are positioned (e.g., in the regions in contact with the first contact electrode 261 and the second contact electrode 262).

Accordingly, the light emitting element 300 disposed between the first electrode 210 and the second electrode 220 may have different diameters depending on positions. For example, the light emitting element 300 may have different diameters measured in another direction perpendicular to the one extension direction.

For example, a first diameter Da of the light emitting element 300 measured in the other direction in the region where the third surface S3 is positioned may be greater than a second diameter Db measured in the region where the second surface S2 is positioned and a third diameter Dc measured in the region where the first surface S1 is positioned. At least some of the first diameter Da, the second diameter Db, and the third diameter Dc may have different values because the insulating film 380 is partially etched during the manufacturing process of the display device 10 or the manufacturing process of the light emitting element 300.

Further, in the light emitting element 300, in the region where the first surface 51 is positioned, a third-first diameter Dc1, measured at the interface between the active layer 330 and the second semiconductor layer 320, and a third-second diameter Dc2, measured at the interface between the second semiconductor layer 320 and the electrode layer 370, may be further defined. Although the third-first diameter Dc1 and the third-second diameter Dc2 are equal in the illustrated embodiment, the present disclosure is not limited thereto. In some embodiments, the third-first diameter Dc1 and the third-second diameter Dc2 may have different values, and the insulating film 380 may be formed to have an inclined outer surface in a cross-sectional view. A description thereof may be provided with reference to other embodiments.

The region of the insulating film 380 where the first surface S1 is positioned (e.g., the region in contact with the first contact electrode 261) may be the region surrounding the active layer 330 and may have a thickness of a certain level or more. The insulating film 380 of the light emitting element 300 according to one embodiment may have a thickness within a range of about 60 nm to about 80 nm, and at least some regions may have a thickness of about 40 nm or more and about 60 nm or less. In the region of the insulating film 380 where the first surface S1 is positioned, such as in the region surrounding the active layer 330, the insulating film 380 may have the thickness of about 40 nm or more even if it is partially etched during the manufacturing process so that exposure of the active layer 330 of the light emitting element 300 may be prevented. Because the insulating film 380 is formed to have a thickness of a certain level or more during the manufacturing process of the light emitting element 300, the light emitting element 300 disposed in the display device 10 may protect the active layer 330 even when the insulating film 380 is partially etched. Accordingly, the luminous efficiency and the luminous reliability of the light emitting element 300 may be improved.

The display device 10 may further include a greater number of insulating layers. According to one embodiment, the display device 10 may further include a fourth insulating layer 540 disposed to protect the first contact electrode 261.

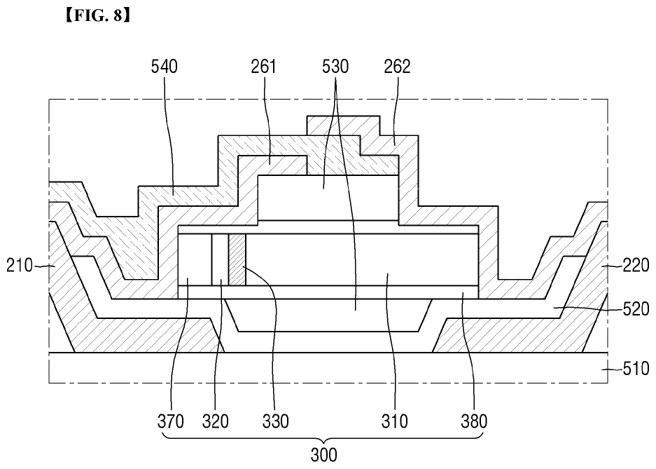

FIG. 8 is a cross-sectional view illustrating a part of a display device according to one embodiment.

Referring to FIG. 8, the display device 10 according to one embodiment may further include the fourth insulating layer 540 disposed on the first contact electrode 261. The display device 10 shown in FIG. 8 is different from the display device 10 shown in FIG. 4 in that it further includes the fourth insulating layer 540 and at least a part of the second contact electrode 262 is disposed on the fourth insulating layer 540. In the following description, redundant descriptions will be omitted.

The display device 10 shown in FIG. 8 may include the fourth insulating layer 540 that is disposed on the first contact electrode 261 and that electrically insulates the first contact electrode 261 and the second contact electrode 262 from each other. The fourth insulating layer 540 may be arranged to cover the first contact electrode 261 and not to overlap (e.g., and offset from) a partial region of the light emitting element 300 such that the light emitting element 300 is connected to the second contact electrode 262. The fourth insulating layer 540 may partially contact the first contact electrode 261 and the third insulating layer 530 on the top surface of the third insulating layer 530. The fourth insulating layer 540 may be disposed on the third insulating layer 530 to cover one end of the first contact electrode 261. Accordingly, the fourth insulating layer 540 may protect the first contact electrode 261 and electrically insulate it from the second contact electrode 262.

A side surface of the fourth insulating layer 540 in a direction in which the second contact electrode 262 is disposed may be aligned with one side surface of the third insulating layer 530. However, the present disclosure is not limited thereto. In some embodiments, the fourth insulating layer 540 may include (or contain) an inorganic insulating material, similar to the second insulating layer 520.

The first contact electrode 261 may be disposed between the first electrode 210 and the fourth insulating layer 540, and the second contact electrode 262 may be disposed on the fourth insulating layer 540. The second contact electrode 262 may partially contact the second insulating layer 520, the third insulating layer 530, the fourth insulating layer 540, the second electrode 220, and the light emitting element 300. One end of the second contact electrode 262 in a direction in which the first electrode 210 is disposed may be disposed on the fourth insulating layer 540.

The passivation layer 550 may be disposed on the fourth insulating layer 540 and the second contact electrode 262 to protect them. Hereinafter, redundant descriptions will be omitted.

Hereinafter, a manufacturing process of the light emitting element 300 according to one embodiment will be described.

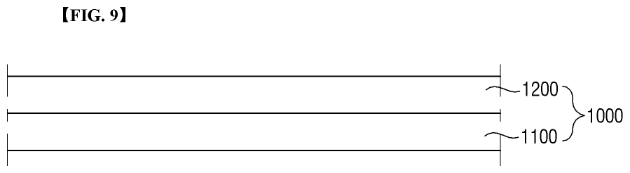

FIGS. 9 to 14 are cross-sectional views showing steps of a manufacturing process of a light emitting element according to one embodiment.

First, referring to FIG. 9, a lower substrate 1000 including a base substrate 1100 and a buffer material layer 1200 formed on the base substrate 1100 is prepared. The base substrate 1100 may include a transparent substrate, such as a sapphire (A1203) substrate and a glass substrate. However, the present disclosure is not limited thereto, and the base substrate 1100 may be formed of a conductive substrate, such as GaN, SiC, ZnO, Si, GaP and GaAs. The following description is directed to an embodiment where the base substrate 1100 is a sapphire (A1203) substrate. Although not limited thereto, the base substrate 1100 may have, for example, a thickness in the range of about 400 μm to about 1500 μm.

A plurality of semiconductor layers are formed on the base substrate 1100.

The plurality of semiconductor layers grown by an epitaxial method may be formed by growing seed crystals. The semiconductor layer may be formed using one of electron beam deposition, physical vapor deposition (PVD), chemical vapor deposition (CVD), plasma laser deposition (PLD), dual-type thermal evaporation, sputtering, and metal organic chemical vapor deposition (MOCVD). In one embodiment, the metal organic chemical vapor deposition (MOCVD) process may be used. However, the present disclosure is not limited thereto.

Typically, a precursor material for forming the plurality of semiconductor layers may be selected to form a target material in a typically selectable range without limitation. For example, the precursor material may be a metal precursor including an alkyl group, such as a methyl group or an ethyl group. Examples of the precursor material may include, but are not limited to, trimethylgallium (Ga(CH₃)₃), trimethylaluminum (Al(CH₃)₃), and triethyl phosphate ((C₂H₅)₃PO₄). Hereinafter, a description is made of the processing order of the method for manufacturing the light emitting element 300 and the layered structure of the light emitting element 300 in detail.

A buffer material layer 1200 is formed on the base substrate 1100. Although one buffer material layer 1200 is deposited in the illustrated embodiment, the present disclosure is not limited thereto, and a plurality of layers may be formed. The buffer material layer 1200 may be disposed to reduce a difference in lattice constant between a first semiconductor 3100 and the base substrate 1100.

For example, the buffer material layer 1200 may include an undoped semiconductor and may be a material including substantially the same material as the first semiconductor 3100 and neither n-type doped nor p-type doped. In an embodiment, the buffer material layer 1200 may be, but is not limited to, at least one of undoped InAlGaN, GaN, AlGaN, InGaN, AlN, or InN. The buffer material layer 1200 may be omitted depending on the base substrate 1100. The following description will be given for an example where the buffer material layer 1200 including an undoped semiconductor is formed on the base substrate 1100.

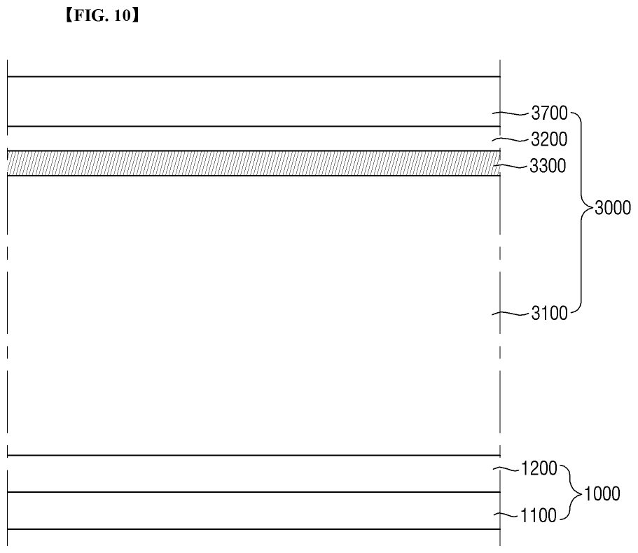

Next, as shown in FIG. 10, the semiconductor structure 3000 is formed on the underlying substrate 1000. The semiconductor structure 3000 may include a first semiconductor 3100, an active layer 3300, a second semiconductor 3200, and an electrode material layer 3700. The plurality of material layers included in the semiconductor structure 3000 may be formed by performing the typical processes as stated above, and the plurality of layers included in the semiconductor structure 3000 may correspond to the respective layers included in the light emitting element 300 according to one embodiment. For exampe, the plurality of material layers may include the same materials as the first semiconductor layer 310, the active layer 330, the second semiconductor layer 320, and the electrode layer 370 of the light emitting element 300.

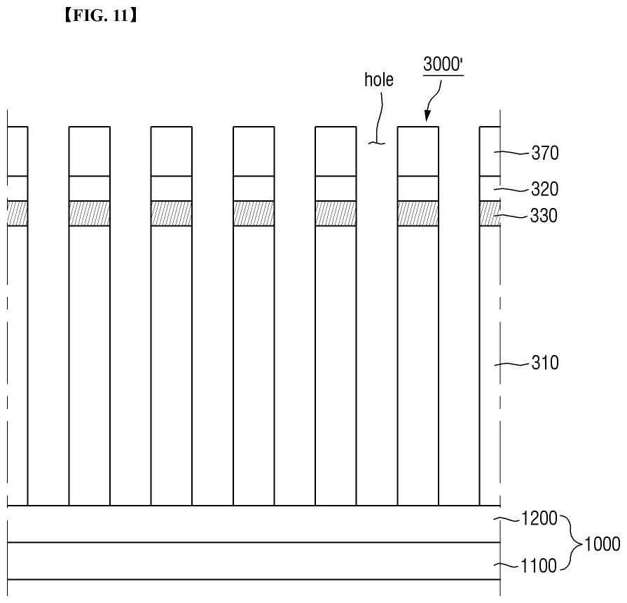

Next, referring to FIG. 11, the semiconductor structure 3000 is etched to form semiconductor cores 3000′ spaced apart from each other. The semiconductor structure 3000 may be etched by a conventional method. For example, the semiconductor structure 3000 may be etched by a method of forming an etch mask layer thereon and etching the semiconductor structure 3000 along the etch mask layer in a direction perpendicular to the lower substrate 1000.

For example, the process of etching the semiconductor structure 3000 may be dry etching, wet etching, reactive ion etching (RIE), inductively coupled plasma reactive ion etching (ICP-RIE), or the like. The dry etching method may be suitable for vertical etching because anisotropic etching can be performed. When using the aforementioned etching technique, Cl₂ or O₂ may be used as an etchant. However, the present disclosure is not limited thereto.

In some embodiments, etching the semiconductor structure 3000 may be carried out with a combination of the dry etching and the wet etching. For example, etching may be performed in a depth direction with the dry etching and then anisotropic etching with the wet etching such that the etched sidewalls are on a plane perpendicular to the surface.

Next, an element rod ROD including the insulating film 380 partially surrounding the outer surface of the semiconductor core 3000′ is formed.

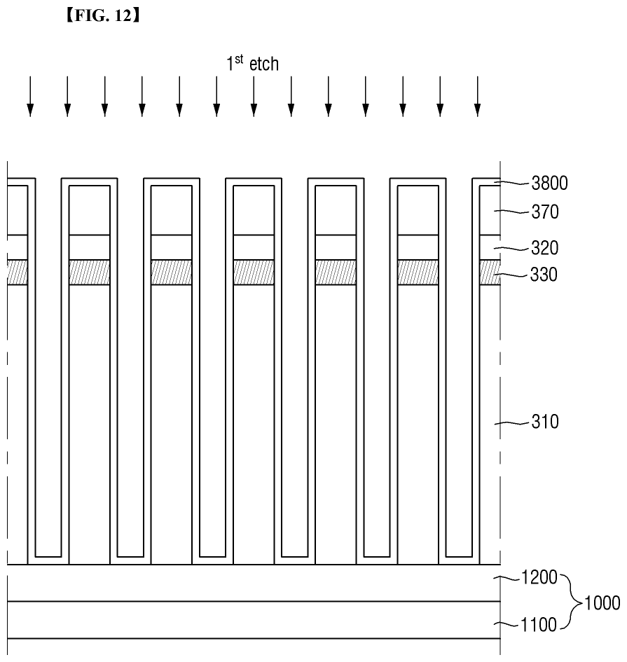

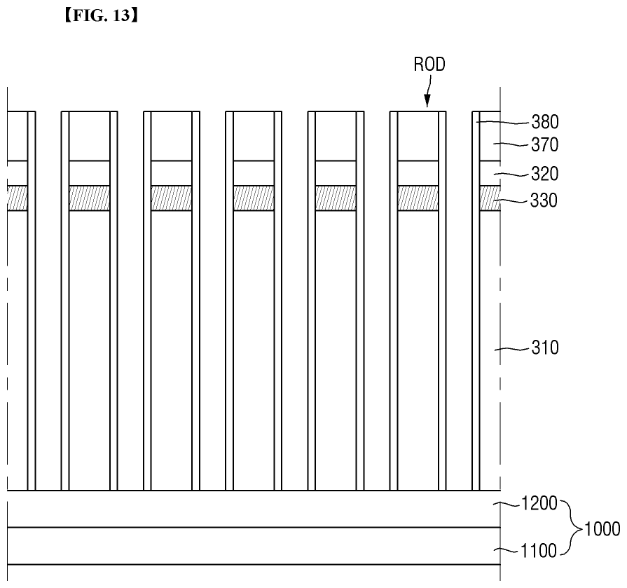

Referring to FIGS. 12 and 13, the insulating film 380 may be formed by forming an insulating coating film 3800 surrounding the outer surface of the semiconductor core 3000′ and then partially removing the insulating coating film 3800 to expose one end of the semiconductor core 3000′ (e.g., the top surface of the electrode layer 370) (see, e.g., 1st etch in FIG. 12).

The insulating coating film 3800, that is, an insulating material, formed on the outer surface of the semiconductor core 3000′ may be formed by using a method of coating or immersing an insulating material on the outer surface of the vertically etched semiconductor core 3000′. However, the present disclosure is not limited thereto. For example, the insulating coating film 3800 may be formed by using atomic layer deposition (ALD).

The insulating coating film 3800 may also be formed on the side surfaces and the top surfaces of the semiconductor cores 3000′ and on the lower substrate 1000 exposed in the region where the semiconductor cores 3000′ are spaced apart from each other. The partial removal of the insulating coating film 3800 may be carried out by etch-back or dry etching as anisotropic etching. In the drawing, the upper surface of the insulating coating film 3800 is removed to expose the electrode layer 370, and in this process, the electrode layer 370 may also be partially removed. For example, in the light emitting element 300, the thickness of the electrode layer 370 of the light emitting element 300 that is manufactured may be smaller than the thickness of the electrode material layer 3700 formed during the manufacturing process. As described above, the thickness of the electrode material layer 3700 may be about 200 nm or more to form the electrode layer 370 of the light emitting element 300 having the thickness of about 20 nm to about 200 nm or about 100 nm to about 200 nm. However, the present disclosure is not limited thereto.

Although it is illustrated in the drawing that the top surface of the electrode layer 370 is exposed and the upper surface of the insulating film 380 is flat, the present disclosure is not limited thereto. In some embodiments, the insulating film 380 may be formed to have a partially curved outer surface in an area where it surrounds the electrode layer 370. In the process of partially removing the insulating coating film 3800, a side surface of the insulating coating film 3800 as well as the top surface thereof may be partially removed so that the insulating film 380 surrounding the multiple layers may be formed with a partially etched end surface. or example, as the top surface of the insulating coating film 3800 is removed, an outer surface of the insulating film 380 adjacent to the electrode layer 370 may be partially removed in the light emitting element 300.

Finally, as shown in FIG. 14, the light emitting element 300 is manufactured by separating the element rod ROD on which the insulating film 380 is formed from the lower substrate 1000.

Through the above-described processes, the light emitting element 300 according to one embodiment may be manufactured. The light emitting element 300 manufactured as described above may be disposed between the first electrode 210 and the second electrode 220, and the display device 10 may be manufactured by arranging the third insulating layer 530, the contact electrode 260, and the like thereon. Next, the manufacturing process of the display device 10 will be described with further reference to other drawings.

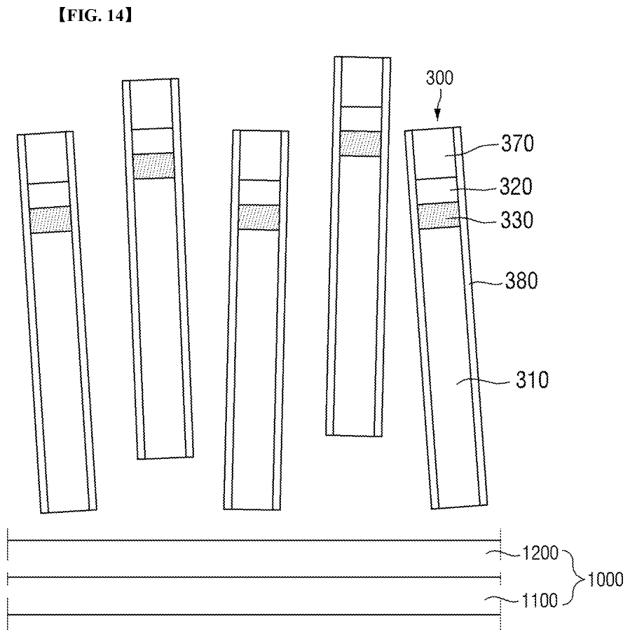

FIGS. 15 to 19 are cross-sectional views illustrating steps of a manufacturing process of a display device according to one embodiment.

First, referring to FIG. 15, the first insulating layer 510, the first internal bank 410 and the second internal bank 420 spaced apart from each other on the first insulating layer 510, the first electrode 210 and the second electrode 220 respectively disposed on the first internal bank 410 and the second internal bank 420, and a second insulating layer 520′ covering the first electrode 210 and the second electrode 220 are prepared. The second insulating material layer 520′ may be partially patterned in a subsequent process to form the second insulating layer 520 of the display device 10. The above members may be formed by patterning a metal, an inorganic material, or an organic material by performing a conventional mask process.

Next, an ink 900 including the light emitting elements 300 is deposited (e.g., sprayed) on the first electrode 210 and the second electrode 220. The ink 900 may include a solvent 910 and the light emitting elements 300 dispersed in the solvent 910. The light emitting elements 300 may be sprayed on the electrodes 210 and 220 while being dispersed in the solvent 910 and may be aligned between the first electrode 210 and the second electrode 220 by an electrical signal applied in a subsequent process.

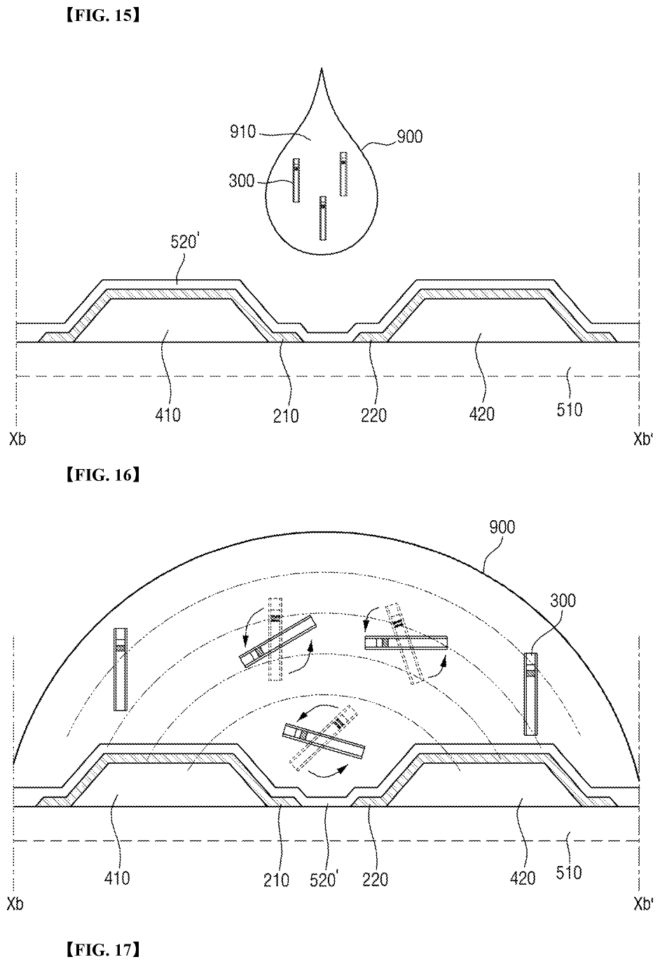

Next, referring to FIG. 16, the electrical signals may be applied to the first electrode 210 and the second electrode 220 to generate an electric field on the ink 900 including the light emitting elements 300. The light emitting elements 300 may receive a dielectrophoretic force induced by the electric field and may be arranged between the first electrode 210 and the second electrode 220 while the orientations and positions thereof are being changed.

Next, referring to FIG. 17, the solvent 910 of the ink 900 is removed. Accordingly, the light emitting element 300 is disposed between the first electrode 210 and the second electrode 220, and the plurality of light emitting elements 300 mounted between the first electrode 210 and the second electrode 220 may be aligned with a specific orientation.

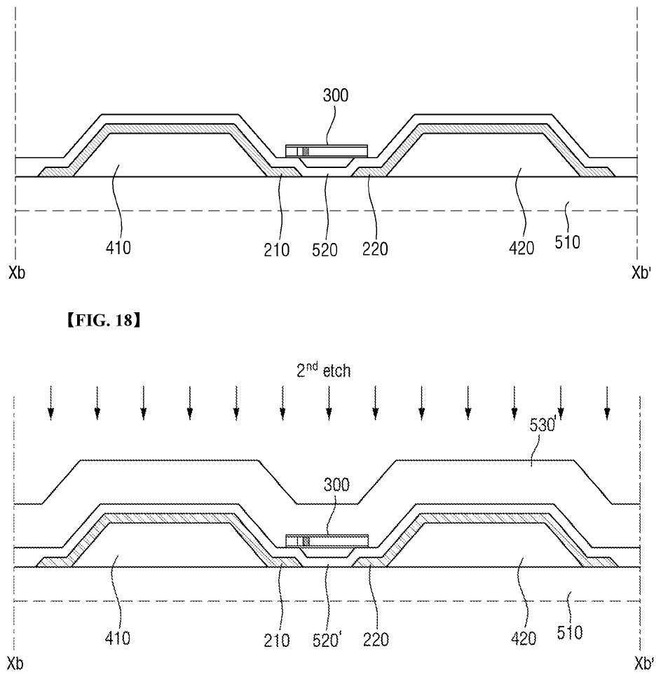

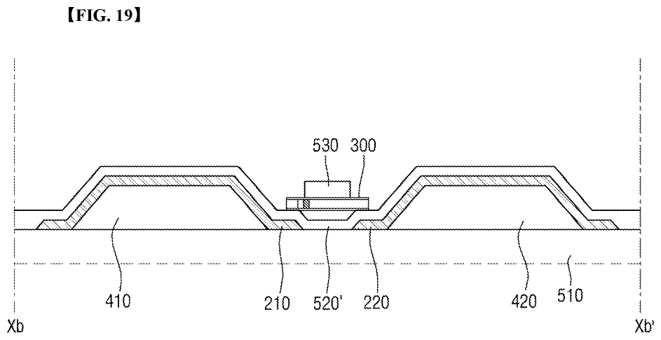

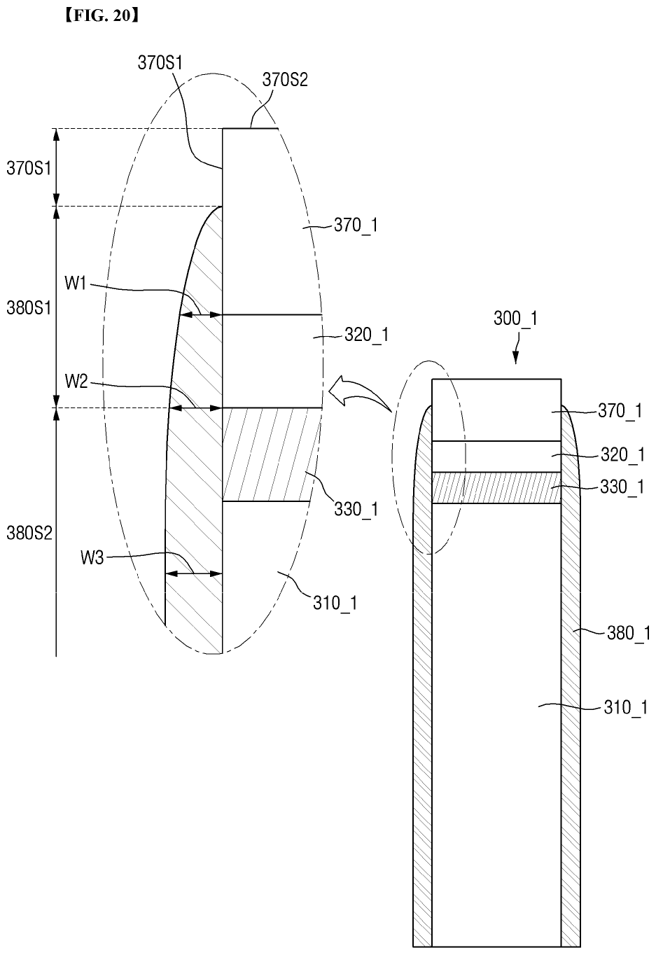

Next, referring to FIGS. 18 and 19, a third insulating material layer 530′ is formed to cover the second insulating material layer 520′ and the light emitting element 300 and then patterned to form the third insulating layer 530 (see, e.g., 2^{nd} etch in FIG. 18). The third insulating material layer 530′ may be partially patterned by the etching process (e.g., the 2^{nd} etch) to form the third insulating layer 530. In the etching process (e.g., the 2^{nd} etch) of the third insulating material layer 530′, the outer surface of the light emitting element 300 may be partially exposed, and the insulating film 380 may be partially etched at this time. Accordingly, the exposed portion of the insulating film 380 where the third insulating layer 530 is not disposed (e.g., the region where the first surface S1 and the second surface S2 shown in FIG. 7 are positioned) may have a thickness smaller than that of the third surface S3, that is, the portion in contact with the third insulating layer 530.

Thereafter, the second insulating material layer 520′ may be patterned to form the second insulating layer 520, and the first contact electrode 261 and the second contact electrode 262 and the passivation layer 550 may be formed to manufacture the display device 10.

As described above, the light emitting element 300 and the display device 10 according to one embodiment may be manufactured. The electrode layer 370 of the light emitting element 300 may be partially etched and may have a reduced thickness during the manufacturing process of the light emitting element 300, and the insulating film 380 of the light emitting element 300 may be partially etched and may have a reduced thickness during the manufacturing process of the light emitting element 300 and the manufacturing process of the display device 10. The light emitting element 300 according to one embodiment may include the electrode layer 370 and the insulating film 380, each having a thickness of a certain level or more, to protect the active layer 330 and allow smooth contact between the electrode layer 370 and the second semiconductor layer 320. Accordingly, the light emitting element 300 included in the display device 10 may secure excellent luminous efficiency and luminous reliability.

Hereinafter, the light emitting element 300 and the display device 10 according to various embodiments will be described.

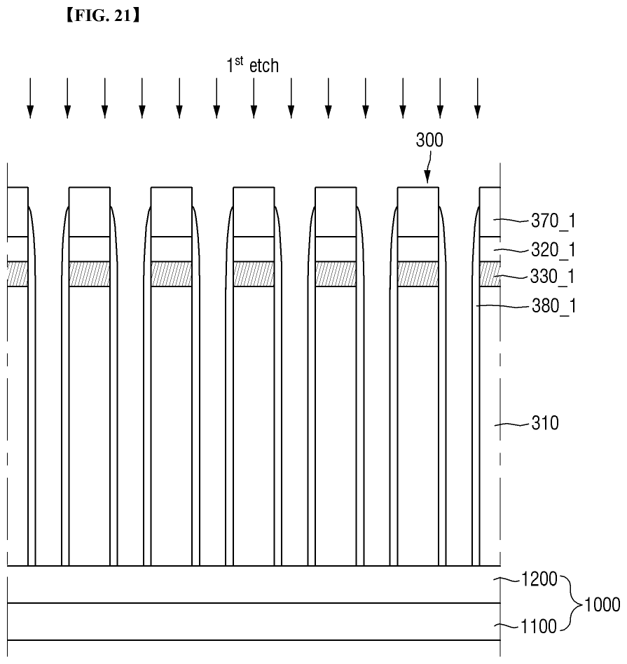

FIG. 20 is a schematic cross-sectional view of a light emitting element according to one embodiment.

Referring to FIG. 20, in a light emitting element 300_1 according to one embodiment, an insulating film 380_1 may have a partially inclined top surface or end surface and may include regions having different thicknesses. The light emitting element 300_1 shown in FIG. 20 is different from the light emitting element 300 shown in FIG. 6 in that the end surface of the insulating film 380_1 has the inclined shape. In addition, the arrangement and structures of the electrode layer 370, the first semiconductor layer 310, the active layer 330, and the like are the same as those of FIG. 6, and differences between these embodiments will be primarily described.

According to one embodiment, the insulating film 380_1 may be disposed to expose a part of the semiconductor core, such as the side surface of an electrode layer 370_1, and the end surface of the portion of the insulating film 380_1 where the electrode layer 370_1 is exposed may have a partially inclined shape. The outer surface of the electrode layer 370_1 may include, on the outer surface thereof, a first exposed surface 370S1 that is exposed without the insulating film 380_1 formed thereon and a second exposed surface 370S2, that is, the other surface opposed to one surface in contact with a second semiconductor layer 320_1. The first exposed surface 370S1 and the second exposed surface 370S2, which are the exposed surfaces without the insulating film 380_1 formed thereon, may be exposed in the process of etching the insulating coating film 3800 during the manufacturing process of the light emitting element 300_1. In the light emitting element 300 shown in FIG. 6, only the top surface of the electrode layer 370 is exposed in the process of etching the insulating coating film 3800. However, in the light emitting element 300_1 shown in FIG. 20, the first exposed surface 370S1 of the electrode layer 370_1 may also be exposed. As illustrated in the drawing, the side surfaces of the electrode layer 370_1 are not entirely but are partially exposed so that a partial region thereof may contact the insulating film 380_1. For example, the side surface of the electrode layer 370_1 may include the region contacting the insulating film 380_1 and the first exposed surface 370S1 that is exposed without the insulating film 380_1 formed thereon.

The insulating film 380_1 may include a first portion 380S1 and a second portion 380S2. The insulating film 380_1 may be formed to expose the first exposed surface 370S1 of the electrode layer 370_1, and the first portion 380S1 may be connected to the first exposed surface 370S1 and curved to have an inclined outer surface. For example, according to one embodiment, the thickness of the first portion 380S1 of the insulating film 380_1 may decrease in one direction in which the light emitting element 300_1 extends. The second portion 380S2 may be connected to the first portion 380S1 to form a flat outer surface. The first portion 380S1 may be disposed to surround a part of the electrode layer 370_1 and the second semiconductor layer 320_1, and the second portion 380S2 may be disposed to surround an active layer 330_1 and a first semiconductor layer 310_1. However, the present disclosure is not limited thereto, and the first portion 380S1 having the inclined outer surface may be disposed to surround a part of the active layer 330_1.

In the light emitting element 300_1 according to the illustrated embodiment, the insulating film 380_1 may have portions having different thicknesses (e.g., the first portion 380S1 and the second portion 380S2). As described above, the insulating film 380_1 may have a thickness of a certain level or more to protect at least the active layer 330_1, and the second portion 380S2 of the insulating film 380_1, which is the portion surrounding the active layer 330_1, may have a thickness greater than that of the first portion 380S1 having the inclined outer surface.

According to one embodiment, in the insulating film 380_1 of the light emitting element 300_1, a third thickness W3, that is, the thickness of the second portion 380S2 surrounding the active layer 330_1, may be greater than the thickness of the first portion 380S1 having the inclined outer surface. Further, at the first portion 380S1, a first thickness W1 measured at the interface between the electrode layer 370_1 and the second semiconductor layer 320_1 and a second thickness W2 measured at the interface between the second semiconductor layer 320_1 and the active layer 330_1 may be different from each other. Due to the inclined outer surface, the first thickness W1 of the portion of the first portion 380S1 adjacent to the first exposed surface 370S1 of the electrode layer 370_1 that is exposed may be smaller than the second thickness W2 of the portion adjacent to the second portion 380S2, and the third thickness W3 may be greater than the first thickness W1 and the second thickness W2. In an embodiment, in the insulating film 380_1, the third thickness W3 of the second portion 380S2 may be within a range of about 60 nm to about 80 nm, and the first thickness W1 and the second thickness W2 of the first portion 380S1 having the inclined outer surface may be smaller than the third thickness W3. However, the present disclosure is not limited thereto.

Such a shape of the light emitting element 300_1 may be formed by concurrently (e.g., simultaneously) etching the upper surface of the insulating film 380_1 at the time of etching the insulating coating film 3800 during the manufacturing process of the light emitting element 300_1.

FIG. 21 is a cross-sectional view partially illustrating a manufacturing process of the light emitting element shown in FIG. 20.

Referring to FIG. 21, in the manufacturing process of the light emitting element 300_1, the insulating coating film 3800 may be partially removed to expose the top surface of the electrode layer 370_1. The process of partially removing the insulating coating film 3800 may be performed by a method of performing etching in a direction perpendicular to the lower substrate 1000. At this time, the side surface of the insulating coating film 3800 may be partially etched. In the light emitting element 300_1 thus formed, the insulating film 380_1 may be etched to form the first portion 380S1 having the inclined outer surface.

As described above, the insulating film 380_1 of the light emitting element 300_1 may be partially etched and may have a reduced thickness during the manufacturing process of the display device 10. In such an embodiment, the thickness relationship of the first thickness W1, the second thickness W2, and the third thickness W3 of the insulating film 380_1 may be changed.

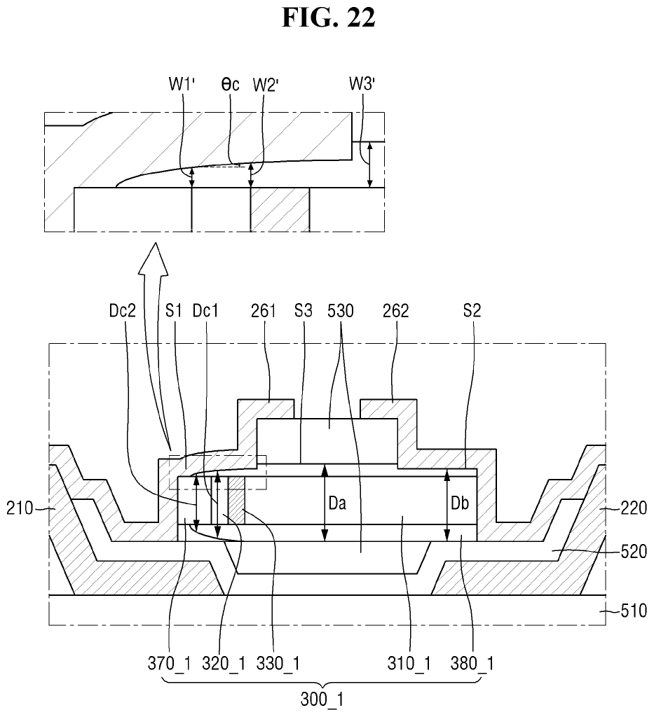

FIG. 22 is a cross-sectional view illustrating a part of the display device including the light emitting element shown in FIG. 20.

FIG. 22 illustrates a cross section passing through both ends of the light emitting element 300_1 of the display device 10 including the light emitting element 300_1 shown in FIG. 20. This embodiment is different from the embodiment shown in FIG. 7 in that the light emitting element 300 is the light emitting element 300_1 shown in FIG. 20. For example, in the embodiment shown in FIG. 22, the insulating film 380_1 of the light emitting element 300_1 includes the first portion 380S1 having the inclined outer surface so that the shape of the first surface S1 where the first contact electrode 261 and the insulating film 380_1 contact each other may be changed. In the following description, redundant descriptions will be omitted.

Referring to FIG. 22, the light emitting element 300_1 may have one side surface, that is, a lower surface, and the other side surface, that is, an upper surface, in a cross-sectional view. The one side surface may contact the second insulating layer 520 and the third insulating layer 530. In the light emitting element 300_1 according to one embodiment, the insulating film 380_1 includes the first portion 380S1 forming the inclined outer surface, and the electrode layer 370_1 includes the second exposed surface 370S2 that is exposed. Accordingly, one side surface of the light emitting element 300_1 may be partially spaced apart from the second insulating layer 520.

As illustrated in the drawing, on the one side surface of the light emitting element 300_1, the first portion 380S1 of the insulating film 380_1 and the second exposed surface 370S2 of the electrode layer 370_1 may be spaced apart from the second insulating layer 520.

The other side surface of the light emitting element 300_1 may contact the first contact electrode 261, the third insulating layer 530, and the second contact electrode 262. On the other side surface, except the first surface S1 contacting the first contact electrode 261, the second surface S2 contacting the second contact electrode 262 and the third surface S3 contacting the third insulating layer 530 are substantially the same as those of the embodiment shown in FIG. 7. On the other hand, the first surface S1 may be positioned across the first portion 380S1 forming the inclined outer surface of the insulating film 380_1 and the second exposed surface 370S2 of the electrode layer 370_1 that is exposed. For example, according to one embodiment, the first contact electrode 261 may contact the second exposed surface 370S2 of the electrode layer 370_1 and the first portion 380S1 of the insulating film 380_1, and the first surface S1 may be formed to be partially inclined or curved.

Further, as described above, the display device 10 may include the region in which the thickness of the insulating film 380 of the light emitting element 300 is partially different. The insulating film 380_1 may have a smaller thickness in the region corresponding to the first surface S1 and the second surface S2 than in the region corresponding to the third surface S3. In the light emitting element 300_1 shown in FIG. 20, the insulating film 380_1 may have the inclined outer surface at the first portion 380S1, and the first thickness W1 measured at the interface between the electrode layer 370_1 and the second semiconductor layer 320_1 may be smaller than the second thickness W2 measured at the interface between the second semiconductor layer 320_1 and the active layer 330_1.

During the manufacturing process of the display device 10, the first portion 380S1 of the insulating film 380_1 may be partially etched so that a first thickness W1′ and a second thickness W2′ may be further reduced. On the other hand, in the insulating film 380_1, the region where the third surface S3 contacts the third insulating layer 530 may not be etched so that a third thickness W3′ measured in this region may be maintained at a constant level. For example, the third thickness W3′ may be greater than the first thickness W1′ and the second thickness W2′. Further, due to the inclined outer surface of the first portion 380S1 of the insulating film 380_1 of the light emitting element 300_1, the first thickness W1′ may be smaller than the second thickness W2′.

Accordingly, the light emitting element 300_1 may have different diameters depending on positions. For example, in the light emitting element 300_1, the first diameter Da, that is, the diameter measured in the other direction in the region corresponding to the third surface S3 may be greater than the second diameter Db measured in the region corresponding to the second surface S2 and the third diameter Dc measured in the region corresponding to the first surface S1. Further, in the light emitting element 300_1, in the region corresponding to the first surface S1, the third-first diameter Dc1 measured at the interface between the active layer 330_1 and the second semiconductor layer 320_1 may be greater than the third-second diameter Dc2 measured at the interface between the second semiconductor layer 320_1 and the electrode layer 370_1. However, the present disclosure is not limited thereto.

According to one embodiment, at the first portion 380S1 of the insulating film 380_1, the first thickness W1′ and the second thickness W2′ may satisfy the following Equation (1):

θc=arctan((W2′−W1′)/D)≤70° Equation 1

where: θc is the inclination angle of the inclined outer surface of the insulating film 380_1, W1′ is the thickness measured at the interface between the electrode layer 370_1 and the second semiconductor layer 320_1 in the insulating film 380_1, W2′ is the thickness measured at the interface between the second semiconductor layer 320_1 and the active layer 330_1 in the insulating film 380_1, and D is the thickness of the second semiconductor layer 320_1.

As described above, the insulating film 380_1 of the light emitting element 300_1 has a thickness of a certain level or more to protect the active layer 330_1 and is disposed to surround at least the active layer 330_1. The light emitting element 300_1 disposed in the display device 10 may be disposed to cover the active layer 330_1 and protect it even if the insulating film 380_1 is partially etched. As illustrated in FIG. 22, in the light emitting element 300_1, the insulating film 380_1 may include the first portion 380S1 in which the inclined outer surface is formed, and the active layer 330_1 may be positioned to overlap the first portion 380S1 of the insulating film 380_1.

To smoothly protect the active layer 330_1, the first portion 380S1 may have a minimum thickness in the region overlapping the active layer 330_1, and the inclination angle θc of the inclined outer surface may be defined. For example, the inclination angle θc of the first portion 380S1 may be measured with respect to the second semiconductor layer 320_1 so that the insulating film 380_1 may protect the active layer 330_1. According to one embodiment, in the insulating film 380_1 of the light emitting element 300_1 of the display device 10, the inclination angle θc of the first portion 380S1 may be about 70° or less, and the second thickness W2′ may be about 40 nm or more. The insulating film 380_1 of the light emitting element 300_1 may have the thickness within the above-described range and may have a thickness sufficient to protect the active layer 330_1 even when it is partially etched to form the first portion 380S1 having the inclined outer surface during the manufacturing process of the light emitting element 300_1. For example, in the light emitting element 300_1 disposed in the display device 10, the thickness (e.g., the second thickness W2′) of the insulating film 380_1 surrounding the active layer 330_1 is within the range of about 40 nm or more and the inclination angle θc is within the range of about 70° or less with respect to the second semiconductor layer 320_1 so that the light emitting element 300_1 may prevent damage of the active layer 330_1. Accordingly, the display device 10 may include the light emitting element 300_1 and have improved luminous efficiency and luminous reliability.

In the insulating film 380, the first thicknesses W1 and W1′ measured at the interface between the second semiconductor layer 320 and the electrode layer 370 may be about 0 nm or more. For example, in the light emitting element 300 according to one embodiment, the insulating film 380 may not be disposed at the interface between the electrode layer 370 and the second semiconductor layer 320.

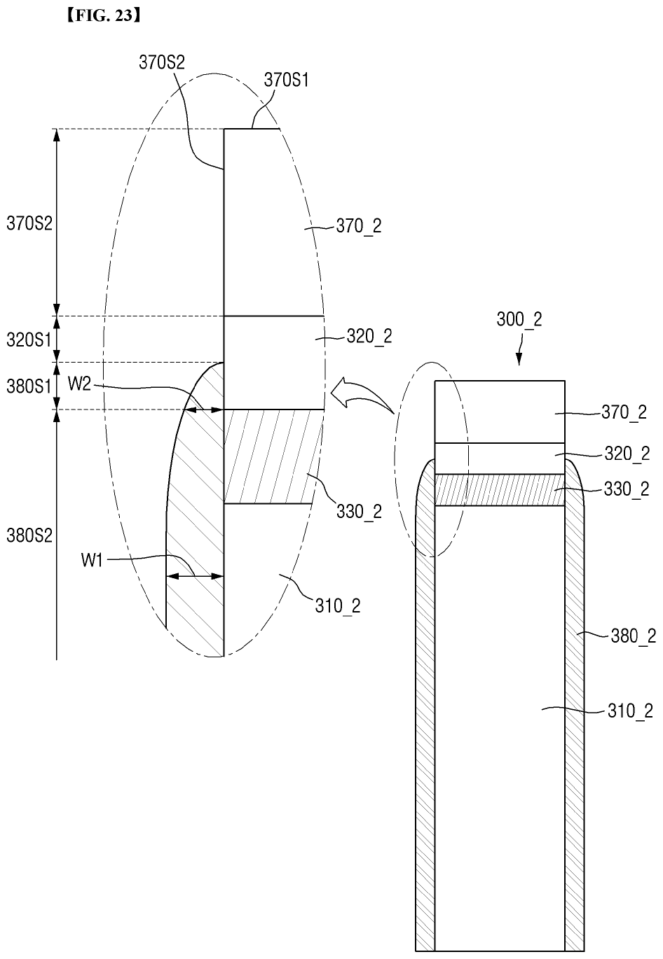

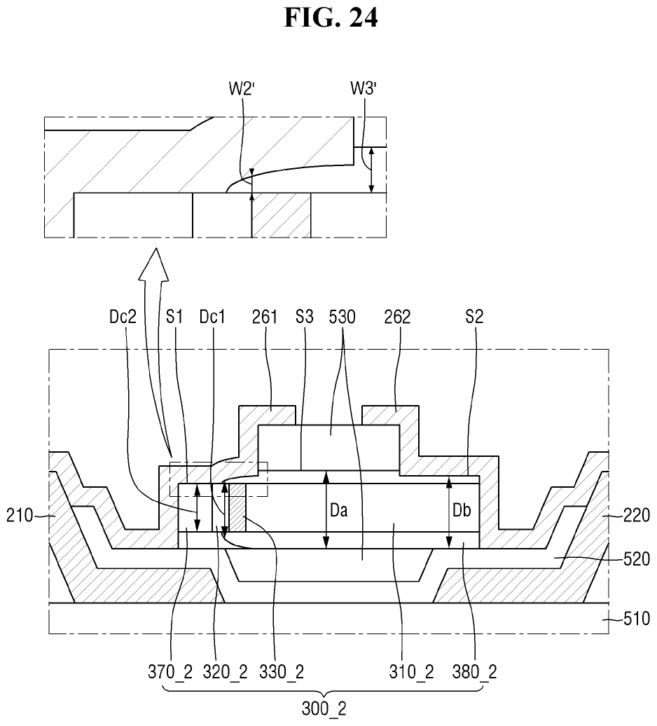

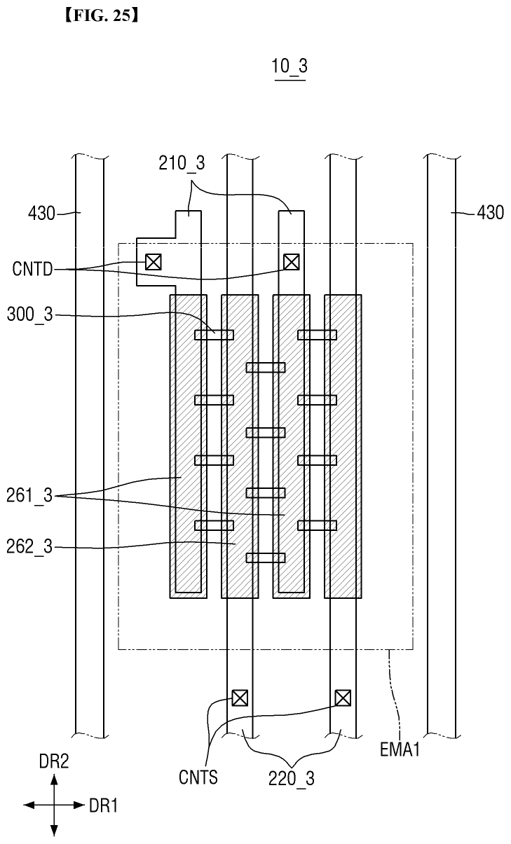

FIG. 23 is a schematic cross-sectional view of a light emitting element according to one embodiment, and FIG. 24 is a cross-sectional view illustrating a part of the display device including the light emitting element of FIG. 23.

Referring to FIG. 23, in a light emitting element 300_2 according to one embodiment, all side surfaces of an electrode layer 370_2 may be exposed and a side surface of a second semiconductor layer 320_2 may be partially exposed. Accordingly, the electrode layer 370_2 may include the first exposed surface 370S1 and the second exposed surface 370S2, and the second semiconductor layer 320_2 may have an exposed surface 32051. The insulating film 380_2 may include the first portion 380S1 connected to the exposed surface 32051 and having an inclined outer surface, and the second portion 380S2 connected to the first portion 380S1 and having a flat outer surface. The first portion 380S1 of the insulating film 380_2 may partially overlap only the second semiconductor layer 320_2 to partially expose the second semiconductor layer 320_2. This embodiment is different from the embodiment shown in FIG. 20 in that the side surface of the second semiconductor layer 320_2 is further exposed. In the insulating film 380_2 of the light emitting element 300_2, the second thickness W2, that is, the thickness of the first portion 380S1, may be smaller than the third thickness W3, that is, the thickness of the second portion 380S2, and the thickness measured at the interface between the electrode layer 370_2 and the second semiconductor layer 320_2 at the first portion 380S1 may be about 0 nm. The other descriptions are the same as those described above with reference to the embodiment shown in FIG. 20 and a detailed description thereof will be omitted.

Referring to FIG. 24, the light emitting element 300_2 may have one side surface, that is, a lower surface, and another side surface, that is, an upper surface, in a cross-sectional view. The one side surface may contact the second insulating layer 520 and the third insulating layer 530. In the light emitting element 300_2 according to one embodiment, the electrode layer 370_2 may include the second exposed surface 370S2 that is exposed, and the second semiconductor layer 320_2 may include the exposed surface 320S1 that is partially exposed. Accordingly, one side surface of the light emitting element 300_2 may be partially spaced apart from the second insulating layer 520. As illustrated in the drawing, on the one side surface of the light emitting element 300_2, the first portion 380S1 of the insulating film 380_2, the second exposed surface 370S2 of the electrode layer 370_2, and the exposed surface 320S1 of the second semiconductor layer 320_2 may be spaced apart from the second insulating layer 520.

The other side surface of the light emitting element 300_2 may contact the first contact electrode 261, the third insulating layer 530, and the second contact electrode 262. The other side surface, except the first surface S1 contacting the first contact electrode 261, the second surface S2 contacting the second contact electrode 262, and the third surface S3 contacting the third insulating layer 530, is substantially the same as that of the embodiment shown in FIG. 20. On the other hand, the first surface S1 may be positioned across the first portion 380S1 forming the inclined outer surface of the insulating film 380_2, the second exposed surface 370S2 of the electrode layer 370_2 that is exposed, and the exposed surface 320S1 of the second semiconductor layer 320_2 that is exposed. For example, according to one embodiment, the first contact electrode 261 may contact the exposed surface 320S1 of the second semiconductor layer 320_2, the second exposed surface 370S2 of the electrode layer 370_2, and the first portion 380S1 of the insulating film 380_2, and the first surface S1 may be partially inclined or curved.

Further, in the light emitting element 300_2 shown in FIG. 23, the insulating film 380_2 has the inclined outer surface at the first portion 380S1 and the second semiconductor layer 320_2 is partially exposed so that the insulating film 380_2 is not disposed at the interface between the second semiconductor layer 320_2 and the electrode layer 370_2, and the second thickness W2 of the insulating film 380_2 may be defined at the interface between the second semiconductor layer 320_2 and the active layer 330_2.

During the manufacturing process of the display device 10, the first portion 380S1 of the insulating film 380_2 is partially etched so that the second thickness W2′ may be further reduced. On the other hand, in the insulating film 380_2, the region where the third surface S3 contacts the third insulating layer 530 is not etched so that the third thickness W3′, that is, the thickness measured in this region, may be maintained at a constant level. For example, the third thickness W3′ may be greater than the second thickness W2′. However, the second thickness W2′ may be within the range of at least about 40 nm in order to protect the active layer 330_2 of the light emitting element 300_2. Accordingly, the light emitting element 300_2 may prevent damage of the active layer 330_2, and the display device 10 may have improved luminous efficiency and luminous reliability.

According to some embodiments, the first electrode 210 and the second electrode 220 may not have the electrode stems 210S and 220S extending in the first direction DR1.

FIG. 25 is a plan view illustrating one sub-pixel of a display device according to one embodiment.

Referring to FIG. 25, in a display device 10_3, a first electrode 210_3 and a second electrode 220_3 may extend in one direction (e.g., in the second direction DR2). The first electrode 210_3 and the second electrode 220_3 may not have the electrode stems 210S and 220S extending in the first direction DR1. The display device 10_3 shown in FIG. 25 is different from the display device 10 shown in FIG. 3 in that the electrode stems 210S and 220S are omitted and one second electrode 220 3 is further included. In the following description, redundant descriptions will be omitted.

As shown in FIG. 25, the plurality of first electrodes 210_3 and second electrodes 220_3 may extend in the second direction DR2 in each sub-pixel PXn. The external bank 430 may also extend in the second direction DR2. The second electrode 220_3 and the external bank 430 may extend to another sub-pixel PXn adjacent in the second direction DR2. Accordingly, each of the sub-pixels PXn adjacent in the second direction DR2 may receive the same electrical signal from the second electrode 220_3.

Different from the display device 10 shown in FIG. 3, in the display device 10_3 shown in FIG. 25, the second electrode contact hole CNTS may be disposed in each second electrode 220_3. The second electrode 220_3 may be electrically connected to the power electrode 162 of the circuit element layer PAL through the second electrode contact hole CNTS disposed in each sub-pixel PXn. Although the second electrode contact hole CNTS is illustrated as being formed in each of the two second electrodes 220_3, the present disclosure is not limited thereto.

On the other hand, the first electrode 210_3 may extend in the second direction DR2 to be terminated at the boundary of each sub-pixel PXn. Each of the sub-pixels PXn adjacent in the second direction DR2 may include the first electrodes 210_3 spaced apart from each other, and they may receive different electrical signals through the first electrode contact holes CNTD. The first electrode 210_3 may have a shape extending in the second direction DR2 and terminated at the boundary between adjacent sub-pixels PXn during the manufacturing process of the display device 10. In the embodiment shown in FIG. 25, the light emitting elements 300 between one first electrode 210_3 and one second electrode 220_3 and the light emitting elements 300 between the other first electrode 210_3 and the other second electrode 220_3 may be connected in parallel.

In the display device 10_3 shown in FIG. 25, some electrodes 210_3 and 220_3 may disposed as floating electrodes without being electrically connected to the circuit element layer PAL through the electrode contact holes CNTD and CNTS. For example, from among the plurality of electrodes 210_3 and 220_3, only the electrodes positioned at the outer part may receive the electrical signals through the electrode contact holes CNTD and CNTS, and the electrodes 210_3 and 220_3 disposed therebetween may not directly receive electrical signals. In such an embodiment, a part of the second electrodes 220_3, (e.g., the second electrode 220_3 disposed between different first electrodes 210_3) may extend in the second direction DR2 and may be terminated at the boundary of each sub-pixel PXn without being disposed in another sub-pixel PXn, similar to the first electrode 210_3. When some of the plurality of electrodes 210_3 and 220_3 are floating electrodes, the light emitting elements 300 disposed therebetween may be partially connected in series as well as in parallel. The external bank 430 may be disposed at the boundary of the sub-pixels PXn adjacent in the first direction DR1 and may extend in the second direction DR2. The external bank 430 may be disposed at the boundary between the sub-pixels PXn adjacent in the second direction DR2 and may extend in the first direction DR1. The description of the external bank 430 is the same as the above description with reference to FIG. 3. Further, the first contact electrode 261_3 and the second contact electrode 262_3 included in the display device 10_3 shown in FIG. 25 are substantially the same as those of the display device 10 shown in FIG. 3.

FIG. 25 illustrates that two first electrodes 210_3 and two second electrodes 220_3 are disposed and alternately spaced apart from each other. However, the present disclosure is not limited thereto, and some electrodes may be omitted or a greater number of electrodes may be disposed in the display device 10_3.

The first electrode 210 and the second electrode 220 of the display device 10 may not necessarily have the shape extending in one direction. The shapes of the first electrode 210 and the second electrode 220 of the display device 10 may not be particularly limited as long as they are placed apart from each other to provide therebetween the space in which the light emitting elements 300 are disposed.

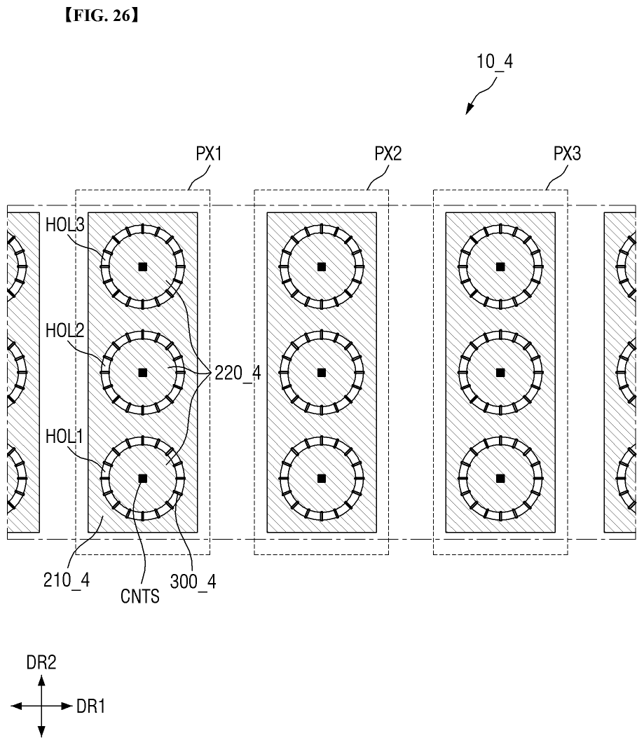

FIG. 26 is a plan view illustrating one pixel of a display device according to one embodiment.

Referring to FIG. 26, at least some areas of a first electrode 210_4 and a second electrode 220_4 of a display device 10_4 according to an embodiment have curved shapes, and the curved area of the first electrode 210_4 may face the curved area of the second electrode 220_4 while being spaced apart from each other. The display device 10_4 shown in FIG. 26 differs from the display device 10 shown in FIG.

2 in that the shapes of the first and second electrodes 210_4 and 220_4 are different from those of the display device 10. In the following description, redundant descriptions will be omitted.

The first electrode 210_4 of the display device 10_4 shown in FIG. 26 may include multiple holes (e.g., multiple openings) HOL. For example, as illustrated in the drawing, the first electrode 210_4 may have a first hole HOL1, a second hole HOL2, and a third hole HOL3 arranged in (e.g., adjacent in) the second direction DR2. However, the present disclosure is not limited to thereto, and the first electrode 210_4 may include a greater number of holes HOL, fewer holes HOL, or even a single hole HOL. Below, the description will be provided for an example where the first electrode 210_4 includes the first hole HOL1, the second hole HOL2, and the third hole HOL3.

In an embodiment, the first hole HOL1, the second hole HOL2, and the third hole HOL3 may have a circular shape in a plan view. Accordingly, the first electrode 210_4 may have curved areas formed by the holes HOL and may face the second electrodes 220_4 in these curved areas. However, the present disclosure is not limited thereto. The first hole HOL1, the second hole HOL2, and the third hole HOL3 are not particularly limited in shape as long as they can provide spaces for accommodating the second electrodes 220_4 therein. By way of example, the holes may have elliptical shapes, polygonal shapes, such as rectangles, or the like in a plan view.

The second electrode 220_4 may be plural in number, and the plurality of second electrodes 220_4 may be disposed in each sub-pixel PXn. By way of example, in each sub-pixel PXn, three second electrodes 220_4 may be disposed in each sub-pixel PXn corresponding to the first to third holes HOL1, HOL2, and HOL3 of the first electrode 210_4. The second electrodes 220_4 may be respectively disposed within the first to third holes HOL1, HOL2, and HOL3, surrounded by the first electrode 210_4.

In an embodiment, the holes HOL of the first electrode 210_4 may have curved surfaces, and each second electrode 220_4 placed in the corresponding hole HOL of the first electrode 210_4 may also have a curved surface and be disposed to face the first electrode 210_4 with a gap therebetween. As illustrated in FIG. 26, the first electrode 210_4 may have the holes HOL having circular shapes in a plan view, and the second electrodes 220_4 may have circular shapes in a plan view. The curved surface of the area of the first electrode 210_4 where each hole HOL is formed may face the curved outer surface of the corresponding one of the second electrodes 220_4 with a gap therebetween. For example, the first electrode 210_4 may be disposed to surround (e.g., to extend around) the outer surfaces of the second electrodes 220_4.

As stated above, light emitting elements 300 may be disposed between the first electrode 210_4 and the second electrode 220_4. The display device 10_4 according to an embodiment may include the second electrode 220_4 having the circular shape and the first electrode 210_4 disposed to surround it, and the light emitting elements 300 may be arranged along the curved outer surface of the second electrode 220_4. As stated above, because the light emitting elements 300 have the shapes extending in one direction, the light emitting elements 300 arranged along the curved outer surface of the second electrode 220_4 in each sub-pixel PXn may be disposed such that their extension directions are directed in different directions. Each sub-pixel PXn may have many different light emission directions depending on the directions in which the extension directions of the light emitting elements 300 are arranged. In the display device 10_4 according to an embodiment, by disposing the first and second electrodes 210_4 and 220_4 to have the curved shapes, the light emitting elements 300 disposed between them may be oriented toward different directions, and lateral visibility (e.g., viewing angle) of the display device 10_4 can be improved.

In concluding the detailed description, those skilled in the art will appreciate that many variations and modifications can be made to the embodiments described herein without substantially departing from the present disclosure. Therefore, the embodiments of the present disclosure described herein are to be used and understood in a generic and descriptive sense and not for purposes of limitation.

1.-23. (canceled)

24. A light emitting element comprising:
a first semiconductor layer doped with a first polarity;
a second semiconductor layer doped with a second polarity different from the first polarity;
an active layer between the first semiconductor layer and the second semiconductor layer in a first direction; and
an insulating film surrounding an outer surface of at least the active layer and extending in the first direction,
wherein a thickness of a first portion of the insulating film surrounding the active layer is in a range of 10% to 16% of a diameter of the active layer.

25. The light emitting element of claim 24, wherein the diameter of the active layer is in a range of 500 nm to 600 nm, and
wherein the thickness of the first portion of the insulating film is in a range of 60 nm to 80 nm.

26. The light emitting element of claim 25, wherein the insulating film has a second portion extending from the first portion and covering a portion of a side surface of the second semiconductor layer, and
wherein a thickness of the second portion is smaller than a thickness of the first portion.

27. The light emitting element of claim 26, wherein a portion of the insulating film surrounding an interface between the active layer and the second semiconductor layer has a thickness of at least 20 nm.

28. The light emitting element of claim 27, wherein the second portion has a curved outer surface such that its thickness decreases in the first direction.

29. The light emitting element of claim 24, further comprising an electrode layer on the second semiconductor layer,
wherein a thickness of the electrode layer is greater than a thickness of the second semiconductor layer.

30. The light emitting element of claim 29, wherein the electrode layer has a thickness in a range of 20 nm to 200 nm.

31. The light emitting element of claim 29, wherein the insulating film surrounds a side surface of the electrode layer.

32. The light emitting element of claim 29, wherein the insulating film surrounds a portion of a side surface of the electrode layer, and
wherein a top surface of the electrode layer is exposed by the insulating film, and the side surface of the electrode layer is partially exposed by the insulating film.

33. The light emitting element of claim 32, wherein the insulating film has a third portion connected to the first portion and surrounding a portion of the side surface of the electrode layer, and
wherein a thickness of the third portion is smaller than a thickness of the first portion.

34. The light emitting element of claim 33, wherein the third portion of the insulating film has a curved outer surface such that its thickness decreases in the first direction.

35. A display device comprising:
a substrate;
a first electrode on the substrate and a second electrode spaced apart from the first electrode;
a light emitting element between the first electrode and the second electrode and electrically connected to the first electrode and the second electrode, the light emitting element comprising:
a first semiconductor layer doped with a first polarity;
a second semiconductor layer doped with a second polarity different from the first polarity;
an active layer between the first semiconductor layer and the second semiconductor layer in a first direction; and
an insulating film surrounding an outer surface of at least the active layer and extending in the first direction;
a first insulating layer under the light emitting element between the first electrode and the second electrode; and
a second insulating layer on the light emitting element and exposing one end and another end of the light emitting element,
wherein the insulating film includes a first portion surrounding the one end of the light emitting element and the active layer, a second portion contacting the second insulating layer, and a third portion surrounding the other end of the light emitting element, and
wherein a thickness of the second portion is greater than that of the first portion and the third portion.

36. The display device of claim 35, further comprising:
a first contact electrode contacting the first electrode and the one end of the light emitting element; and
a second contact electrode contacting the second electrode and the other end of the light emitting element.

37. The display device of claim 36, wherein the light emitting element further comprises an electrode layer on the second semiconductor layer and having a thickness greater than that of the second semiconductor layer,
wherein the first contact electrode contacts the first portion of the insulating film and the electrode layer, and
wherein the second contact electrode contacts the third portion of the insulating film and the first semiconductor layer.

38. The display device of claim 37, wherein the first portion of the insulating film surrounds a portion of a side surface of the electrode layer, and
wherein a top surface of the electrode layer is exposed by the insulating film, and the side surface of the electrode layer is partially exposed by the insulating film.

39. The display device of claim 38, wherein the first contact electrode contacts a portion of the side surface and the top surface of the electrode layer.

40. The display device of claim 37, wherein the first portion of the insulating film has a curved outer surface such that its thickness decreases in the first direction.

41. The display device of claim 40, wherein in the first portion, a first thickness measured at an interface between the second semiconductor layer and the electrode layer and a second thickness measured at an interface between the second semiconductor layer and the active layer satisfy the following Equation (1):
θc=arctan((W2′−W1′)/D)≤70° Equation 1
wherein: θc is an inclination angle of an inclined outer surface of the first portion of the insulating film;
W1′ is a thickness measured at an interface between the electrode layer and the second semiconductor layer in the first portion of the insulating film;
W2′ is a thickness measured at an interface between the second semiconductor layer and the active layer in the first portion of the insulating film; and
D is a thickness of the second semiconductor layer.

42. The display device of claim 41, wherein the second thickness is 20 nm or more, and
wherein a thickness of the first portion surrounding the active layer is 40 nm or more.

43. The display device of claim 37, wherein the electrode layer has a thickness in a range of 20 nm to 200 nm.

44. The display device of claim 35, wherein a thickness of the second portion is in a range of 10% to 16% of a diameter of the active layer.

45. The display device of claim 44, wherein the diameter of the active layer is in a range of 500 nm to 600 nm, and
wherein the thickness of the second portion of the insulating film is in a range of 60 nm to 80 nm.

46. The display device of claim 45, wherein a first diameter of the light emitting element measured at the second portion of the insulating film is greater than a second diameter of the light emitting element measured at the first portion of the insulating film and a third diameter of the light emitting element measured at the third portion of the insulating film.
